(19) United States
(12) Patent Application Publication
(10) Pub. No.: US 2014/0295159 A1
(43) Pub. Date: Oct. 2, 2014

(54) CURABLE RESIN COMPOSITION, FILM, PREPREG, LAMINATE, CURED ARTICLE, AND COMPOSITE ARTICLE

(71) Applicants: Masafumi Kawasaki, Tokyo (JP); Yuuki Hayashi, Tokyo (JP)

(72) Inventors: Masafumi Kawasaki, Tokyo (JP); Yuuki Hayashi, Tokyo (JP)

(73) Assignee: ZEON CORPORATION, Tokyo (JP)

(21) Appl. No.: 14/240,246

(22) PCT Filed: Aug. 21, 2012
(86) PCT No.: PCT/JP2012/071091

§ 371 Date: Jun. 16, 2014

(30) Foreign Application Priority Data
Aug. 23, 2011 (JP) 2011-181678
Aug. 23, 2011 (JP) 2011-181684

(51) Int. Cl. H05K 1/03; B32B 17/10

(52) U.S. Cl. CPC H05K 1/036; B32B 17/10733; H05K 1/0306
USPC 428/216; 428/413; 442/180; 428/221; 523/438

(57) ABSTRACT

A curable resin composition which contains an epoxy compound (A1), active ester compound (A2), filler (A3), and alicyclic olefin polymer (A4) containing groups which have reactivity with respect to epoxy groups, wherein a ratio of content of the alicyclic olefin polymer (A4) to 100 parts by weight of said epoxy compound (A1) is 2 to 50 parts by weight is provided. According to the present invention, a curable resin composition which is excellent in resin fluidity and which can give a cured article which is low in linear expansion and is excellent in wire embedding flatness, electrical characteristics, and heat resistance can be provided.

### TECHNICAL FIELD

The present invention relates to a curable resin composition, film, prepreg, laminate, cured article, and composite article.

### BACKGROUND ART

Along with the pursuit of smaller sizes, increased functions, and faster communications in electronic equipment, further higher densities of the circuit boards which are used for the electronic equipment have been sought. To meet such demands for higher densities, circuit boards are being made multilayered. Such multilayer circuit boards are, for example, formed by taking an inside layer board which is comprised of an electrical insulating layer and a conductor layer which is formed on its surface, laminating an electrical insulating layer over it, forming a conductor layer over this electrical insulating layer, and further repeating this lamination of an electrical insulating layer and formation of a conductor layer.

As the material for forming the electrical insulating layer of such multilayer circuit boards, in general ceramics and thermosetting resins are being used. Among these, as thermosetting resins, epoxy resins are being widely used since they are excellent in the point of the balance of economy and performance.

As the epoxy resin material for forming such an electrical insulating layer, for example, Patent Document 1 discloses a resin composition which contains a polyfunctional epoxy resin, phenol-based curing agent and/or active ester-type curing agent, thermoplastic resin, inorganic filler, and quaternary phosphonium-type curing accelerator.

Further, Patent Document 2 discloses a resin composition which contains an epoxy resin, a curing agent constituted by an active ester compound, a curing accelerator, and a filler and has a content of the active ester compound of 118 to 200 parts by weight with respect to 100 parts by weight of the epoxy resin.

Furthermore, Patent Document 3 discloses a resin composition which contains a cycloolefin resin, epoxy resin, a compound which has active ester groups, and a filler. Note that, in this Patent Document 3, the amount of the cycloolefin resin in the specific examples is made a relatively large amount of 83 to 99 wt % in the total resin ingredients.

### PRIOR ART DOCUMENTS

### Patent Documents

Patent Document 1: WO2010/87526A
Patent Document 2: Japanese Patent Publication No. 2011-32296A
Patent Document 3: Japanese Patent Publication No. 2006-278994A

### SUMMARY OF THE INVENTION

### Problem to be Solved by the Invention

However, the inventors studied this and found that when using the resin compositions which are described in Patent Document 1 and Patent Document 2 to form insulating resin layers of a printed circuit board for electronic material-use, there is the problem that the resin layer is large in linear expansion coefficient and the multilayer board ends up greatly deforming and the problem that the heat resistance, waterproofness, and other aspects of reliability are not sufficient.

Further, the resin composition which is described in the above Patent Document 3 is inferior in resin fluidity, so when using this to form an insulating resin layer of a printed circuit board for electronic material-use, the pattern embedding ability of the circuit board is not sufficient and therefore the demands for higher performance of multilayer circuit boards cannot be met.

An object of the present invention is to provide a curable resin composition which is excellent in resin fluidity and which gives a cured article which is low in linear expansion and excellent in wire embedding flatness, electrical characteristics, and heat resistance and a film, prepreg, laminate, cured article, and composite article which are obtained using the same.

### Means for Solving the Problems

The inventors engaged in intensive research to achieve the above object and as a result discovered that a resin composition which contains an epoxy compound, active ester compound, filler, and alicyclic olefin polymer containing groups which have reactivity to epoxy groups in predetermined ratios is excellent in resin fluidity and can give a cured article which is low in linear expansion and excellent in wire embedding flatness, electrical characteristics, and heat resistance and thereby completed the present invention.

That is, according to the present invention,

[1] a curable resin composition containing an epoxy compound (A1), active ester compound (A2), filler (A3), and alicyclic olefin polymer (A4) containing groups which have reactivity to epoxy groups, wherein a ratio of content of the alicyclic olefin polymer (A4) to 100 parts by weight of the epoxy compound (A1) is 2 to 50 parts by weight,
[2] the curable resin composition as set forth in the above [1] wherein a ratio of epoxy groups of the epoxy compound (A1), and active ester groups of the active ester compound (A2) and groups which have reactivity to epoxy groups of the alicyclic olefin polymer (A4) is 0.8 to 1.2 as an equivalent ratio of “epoxy groups/(active ester groups+groups which have reactivity with respect to epoxy groups)”,
[3] a film which is comprised of the curable resin composition as set forth in the above [1] or [2],
[4] a film which has an adhesive layer which is comprised of the curable resin composition as set forth in the above [1] or [2] and a plateable layer which is comprised of a plateable layer-use resin composition,
[5] the film as set forth in the above [4], wherein the above plateable layer-use resin composition contains an alicyclic olefin polymer (B1) containing polar groups and a curing agent (B2),
[6] the film as set forth in the above [4] or [5], wherein the above adhesive layer has a thickness of 10 to 100 μm and the above plateable layer has a thickness of 1 to 10
[7] a prepreg obtained by impregnating the curable resin composition as set forth in the above [1] or [2] in a fiber base material,
[8] a prepreg which is comprised of the film as set forth in any one of the above [4] to [6] and a fiber base material,
[9] a laminate obtained by laminating the film as set forth in any one of the above [3] to [6] or the prepreg as set forth in the above [7] or [8] on a base material,
[10] a cured article obtained by curing the curable resin composition as set forth in the above [1] or [2], the film as set forth in any one of the above [3] to [6], the prepreg as set forth in the above [7] or [8], or the laminate as set forth in the above [9],
[11] a composite article obtained by forming a conductor layer on the surface of the cured article as set forth in the above [10] by electroless plating, and
[12] a substrate for electronic material-use which is comprised of the cured article as set forth in [10] or the composite article as set forth in [11] as a component material are provided.

### Effects of the Invention

According to the present invention, there are provided a curable resin composition which is excellent in resin fluidity and which can give a cured article which is low in linear expansion and excellent in wire embedding flatness, electrical characteristics, and heat resistance and a film, prepreg, laminate, cured article, and composite article which are obtained using the same.

### DESCRIPTION OF EMBODIMENTS

The curable resin composition of the present invention is a composition which contains an epoxy compound (A1), active ester compound (A2), filler (A3), and alicyclic olefin polymer (A4) containing groups which have reactivity to epoxy groups, wherein a ratio of content of the above alicyclic olefin polymer (A4) with respect to 100 parts by weight of the above epoxy compound (A1) is 2 to 50 parts by weight.

(Epoxy Compound (A1))

The epoxy compound (A1) used in the present invention may be one which has one or more epoxy groups, but in the present invention, a polyepoxy compound which has at least two epoxy structures in its molecule is preferable.

As examples of the epoxy compound (A1), a phenol novolac-type epoxy compound, cresol novolac-type epoxy compound, cresol-type epoxy compound, bisphenol A-type epoxy compound, bisphenol F-type epoxy compound, polyphenol-type epoxy compound, brominated bisphenol A-type epoxy compound, brominated bisphenol F-type epoxy compound, hydrogenated bisphenol A-type epoxy compound, or other glycidyl ether-type epoxy compound, alicyclic epoxy compound, glycidyl ester-type epoxy compound, glycidyl amine-type epoxy compound, isocyanulate-type epoxy compound, epoxy compound which has an alicyclic olefin structure or epoxy compound which has a fluorene structure, etc. may be mentioned. Among these, from the viewpoint that it is possible to improve the mechanical properties of the obtained film, prepreg, laminate, and cured article, a bisphenol A-type epoxy compound, polyphenol-type epoxy compound, or epoxy compound which has an alicyclic olefin structure or fluorene structure is preferable. Furthermore, from the viewpoint of improving the resin fluidity of the resin composition, an epoxy compound which has an alicyclic olefin structure is particularly preferable. Note that, these may be used as single type alone or as two or more types combined.

As the bisphenol A type epoxy compounds, for example, product names “jER827, jER828, jER828EL, jER828XA, and jER834” (above all made by Mitsubishi Chemical Corporation), product names “EPICLON 840, EPICLON 840-S, EPICLON 850, EPICLON 850-S, and EPICLON 850-LC” (above all made by DIC Corporation, “EPICLON” is a registered trademark), etc. may be mentioned. As the polyphenol type epoxy compound, for example, product names “1032H60 and XY-4000” (above all made by Mitsubishi Chemical Corporation), etc. may be mentioned. As epoxy compounds which have alicyclic olefin structures or fluorene structures, epoxy compounds which have dicyclopentadiene structure (for example, product names “EPICLON HP7200L, EPICLON HP7200, EPICLON HP7200H, EPICLON HP7200HH, and EPICLON HP7200HHH” (above all made by DIC Corporation); product name “Tactix 558” (made by Huntsman Advanced Materials); product names “XD-1000-1L and XD-1000-2L” (above all made by Nippon Kayaku Co., Ltd.)), epoxy compounds which have fluorene structure (for example, product names “Oncoat EX-1010, Oncoat EX-1011, Oncoat EX-1012, Oncoat EX-1020, Oncoat EX-1030, Oncoat EX-1040, Oncoat EX-1050, and Oncoat EX-1051” (above all made by NAGASE & CO., LTD. “Oncoat” is a registered trademark); product names “OGSOL PG-100, OGSOL EG-200, and OGSOL ES-250)” (above all made by Osaka Gas Chemicals, Co., Ltd. “OGSOL” is a registered trademark)), etc. may be mentioned.

(Active Ester Compound (A2))

The active ester compound (A2) used in the present invention may be one which has active ester groups, but in the present invention, a compound which has at least two active ester groups in its molecule is preferable. The active ester compound (A2) acts as a curing agent for the epoxy compound (A1).

As the active ester compound (A2), from the viewpoint of the heat resistance etc., an active ester compound which is obtained by reaction of a carboxylic acid compound and/or thiocarboxylic acid compound and hydroxy compound and/or thiol compound is preferable, an active ester compound which is obtained by reaction of a carboxylic acid compound and one or more compounds selected from the group of a phenol compound, naphthol compound, and thiol compound is more preferable, and in the present invention, an aromatic compound which is obtained by reaction of a carboxylic acid compound and an aromatic compound which has a phenolic hydroxy group and which has at least two active ester groups in its molecule is particularly preferable. The active ester compound (A2) may be a linear one or multibranched one. If illustrating the case where the active ester compound (A2) is derived from a compound which has at least two carboxylic acids in its molecule, when such a compound which has at least two carboxylic acids in its molecule contains an aliphatic chain, it is possible to raise the compatibility with the epoxy resin, while when it has an aromatic ring, it is possible to raise the heat resistance.

As specific examples of the carboxylic acid compound for forming an active ester compound (A2), benzoic acid, acetic acid, succinic acid, maleic acid, itaconic acid, phthalic acid, isophthalic acid, terephthalic acid, pyromellitic acid, etc. may be mentioned. Among these as well, from the viewpoint of the heat resistance, succinic acid, maleic acid, itaconic acid, phthalic acid, isophthalic acid, and terephthalic acid are preferable, phthalic acid, isophthalic acid, and terephthalic acid are particularly preferable, and isophthalic acid and terephthalic acid are furthermore preferable.

As specific examples of the thiocarboxylic acid compound for forming the active ester compound (A2), thioacetic acid, thiobenzoic acid, etc. may be mentioned.

As specific examples of the phenol compound and naphthol compound for forming the active ester compound (A2), hydroquinone, resorcine, bisphenol A, bisphenol F, bisphenol S, phenol phthalein, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, fluoroglycine, benzenetriol, dicyclopentadienyl diphenol, phenol novolac, etc. may be mentioned. Among these as well, from the viewpoint of the heat resistance and solubility, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, dicyclopentadienyl diphenol, and phenol novolac are preferable, dihydroxybenzophenone, trihydroxybenzophenone, tetrahydroxybenzophenone, dicyclopentadienyl diphenol, and phenol novolac are more preferable, and diyclopentadienyl diphenol and phenol novolac are further more preferable.

As specific examples of the thiol compound for forming the active ester compound (A2), benzene dithiol, triazine dithiol, etc. may be mentioned.

In the present invention, as the active ester compound (A2), for example, the active ester compounds which are disclosed in Japanese Patent Publication No. 2002-12650A and Japanese Patent Publication No. 2004-277460A or commercially available ones may be used. As the commercially available active ester compounds, for example, product names “EXB9451, EXB9460, EXB9460S, and HPC-8000-65T” (above made by DIC Corporation), product name “DC808” (made by Japan Epoxy Resin Corporation), product name “YLH1026” (made by Japan Epoxy Resin Corporation), etc. may be mentioned.

The method of production of the active ester compound (A2) is not particularly limited. A known method may be used for production, but, for example, the compound may be obtained by a condensation reaction of the carboxylic acid compound and/or thiocarboxylic acid compound and hydroxy compound and/or thiol compound.

The amount of the active ester compound (A2) in the curable resin composition of the present invention is preferably 20 to 120 parts by weight with respect to 100 parts by weight of the epoxy compound (A1), more preferably 40 to 100 parts by weight, furthermore preferably 50 to 90 parts by weight in range. By making the amount of the active ester compound (A2) in the above range, it is possible to improve the cured article in electrical characteristics and low heat buildup and linear expansion coefficient.

(Filler (A3))

The filler (A3) used in the present invention is not particularly limited so long as one which is generally used industrially. Either of an inorganic filler and organic filler may be used, but the inorganic filler is preferably used. By mixing in the filler (A3), when making a cured article, the obtained cured article can be made one which is low in linear expansion.

As specific examples of the inorganic filler, calcium carbonate, magnesium carbonate, barium carbonate, zinc oxide, titanium oxide, magnesium oxide, magnesium silicate, calcium silicate, zirconium silicate, hydrated alumina, magnesium hydroxide, aluminum hydroxide, barium sulfate, silica, talc, clay, etc. may be mentioned. Among these as well, ones which do not break down or dissolve by oxidizing compounds such as the aqueous solution of permanganate which is used for the surface roughening treatment of the cured article are preferable. Among these, in particular, silica is preferable since fine particles can be easily obtained. Note that, the inorganic filler may also be one which is treated by a silane coupling agent or treated by stearic acid or other organic acids.

Further, as the filler (A3), a nonconductive one which does not cause a drop in the dielectric characteristics when made a resin layer is preferable. Further, the filler (A3) is not particularly limited in form. A spherical shape, fiber shape, plate shape, etc. are possible, but to improve the dispersibility and the resin fluidity of the resin composition, a fine spherical shape is preferable.

The average particle diameter of the filler (A3) is preferably 0.05 to 1.5 μm, more preferably 0.1 to 1 μm. By the average particle diameter of the filler (A3) being in the above range, it is possible to improve the fluidity of the curable resin composition while lowering the linear expansion coefficient in the case of made a resin layer. Note that, the average particle diameter can be measured by a particle size distribution measurement apparatus.

The amount of the filler (A3) in the resin composition (in the case including an organic solvent, in the resin composition excluding the organic solvent) is preferably 30 to 90 wt %, more preferably 40 to 80 wt %, furthermore preferably 50 to 70 wt %.

(Alicyclic Olefin Polymer (A4) Containing Groups which have Reactivity to Epoxy Groups)

The curable resin composition of the present invention contains, in addition to the above-mentioned epoxy compound (A1), active ester compound (A2), and filler (A3), an alicyclic olefin polymer (A4) containing groups which have reactivity to epoxy groups. As the alicyclic structure which forms the alicyclic olefin polymer (A4) containing groups which have reactivity to epoxy groups used in the present invention (below, suitably abbreviated as “alicyclic olefin polymer (A4)”), a cycloalkane structure, cycloalkene structure, etc. may be mentioned, but from the viewpoint of the mechanical strength, heat resistance, etc., a cycloalkane structure is preferable. Further, as the alicyclic structure, a monocyclic structure, polycyclic structure, condensed polycyclic structure, bridged ring structure, or polycyclic structure comprised of a combination of these etc. may be mentioned. The number of carbon atoms which form the alicyclic structure is not particularly limited, but is usually 4 to 30, preferably 5 to 20, more preferably 5 to 15 in range. When the number of carbon atoms which form the cyclic structure is in this range, the various characteristics of the mechanical strength, heat resistance, and shapeability are balanced to a high degree, so this is preferred. Further, the alicyclic olefin polymer (A4) is usually a thermoplastic one.

The alicyclic structure of the alicyclic olefin polymer (A4) is comprised of olefin monomer units which have cyclic structures formed by carbon atoms (below, referred to as “cyclic olefin units”). The alicyclic olefin polymer (A4) may include not only alicyclic olefin units, but also other monomer units. The ratio of the alicyclic olefin units in the alicyclic olefin polymer (A4) is not particularly limited, but is usually 30 to 100 wt %, preferably 50 to 100 wt %, more preferably 70 to 100 wt %. If the ratio of the alicyclic olefin units is too small, the heat resistance becomes inferior, so this is not preferred. The repeating units other than the alicyclic olefin units are not particularly limited and are suitably selected in accordance with the objective.

The groups which have reactivity to epoxy groups which the alicyclic olefin polymer (A4) has (below, suitably abbreviated as “epoxy reactive groups”) are not particularly limited, but alcoholic hydroxy groups, phenolic hydroxy groups, carboxyl groups, alkoxyl groups, epoxy groups, glycidyl groups, oxycarbonyl groups, carbonyl groups, amino groups, carboxylic anhydride groups, sulfonic acid groups, phosphoric acid groups, etc. may be mentioned, but among these as well, carboxyl groups, carboxylic anhydride groups, and phenolic hydroxy groups are preferable, while carboxylic anhydride groups are more preferable. Note that, the alicyclic olefin polymer (A4) may be one which has two or more types of epoxy reactive groups. The epoxy reactive groups may be bonded as two or more groups to a single monomer unit, may be bonded to alicyclic olefin units, and may be bonded to other monomer units. Further, the epoxy reactive groups of the alicyclic olefin polymer (A4) may be directly bonded to the atoms which form the mainchain of the polymer or may be bonded through methylene groups, oxy groups, oxycarbonyloxyalkylene groups, phenylene groups, and other bivalent groups. The content of the monomer units which have epoxy reactive groups in the alicyclic olefin polymer (A4) is not particularly limited, but is usually 4 to 60 mol % in 100 mol % of the total monomer units which form the alicyclic olefin polymer (A4), preferably 8 to 50 mol %.

The alicyclic olefin polymer (A4) which used in the present invention can, for example, be obtained by the following methods. That is, (1) the method of polymerizing an alicyclic olefin which has epoxy reactive groups while adding other monomers in accordance with need, (2) the method of copolymerizing an alicyclic olefin which does not have epoxy reactive groups together with the monomer which has the epoxy reactive groups, (3) the method of polymerizing an aromatic olefin which has epoxy reactive groups while adding other monomers in accordance with need and thereby hydrogenating the aromatic ring parts of the obtained polymer, (4) the method of copolymerizing an aromatic olefin which does not have epoxy reactive groups together with the monomer which has the epoxy reactive groups and hydrogenating the aromatic ring parts of the polymer obtained by this, or (5) the method of introducing a compound which has epoxy reactive groups in an alicyclic olefin polymer which does not have epoxy reactive groups by a modification reaction, (6) the method of hydrolyzing the epoxy reactive groups of the alicyclic olefin polymer which has epoxy reactive groups (for example, carboxylic acid ester groups etc.) which is obtained by the above (1) to (5) to convert them to other epoxy reactive groups (for example, carboxyl groups), etc. may be used to obtain it. Among these as well, a polymer which is obtained by the method of the above (1) is suitable.

As the polymerization method for obtaining the alicyclic olefin polymer (A4) used in the present invention, ring opening polymerization or addition polymerization may be used, but in the case of ring opening polymerization, the obtained ring-opened polymer is preferably hydrogenated.

As specific examples of the alicyclic olefin which has epoxy reactive groups which can be used as a monomer which has epoxy reactive groups, 5-hydroxycarbonylbicyclo[2.2.1]hept-2-ene, 5-methyl-5-hydroxycarbonylbicyclo[2.2.1]hept-2-ene, 5-carboxymethyl-5-hydroxycarbonylbicyclo[2.2.1]hept-2-ene, 9-hydroxycarbonyltetracyclo[6.2.1.1^{3,6}.0^{2,7}]dodec-4-ene, 9-methyl-9-hydroxycarbonyltetracyclo[6.2.1.1^{3,6}.0^{2,7}]dodec-4-ene, 9-carboxymethyl-9-hydroxycarbonyltetracyclo[6.2.1.1^{3,6}.0^{2,7}]dodec-4-ene, 5-exo-6-endo-dihydroxycarbonylbicyclo[2.2.1]hept-2-ene, 9-exo-10-endo-dihydroxycarbonyltetracyclo[6.2.1.1^{3,6}.0^{2,7}]dodec-4-ene, and other alicyclic olefins which have carboxyl groups; bicyclo[2.2.1]hept-2-ene-5,6-dicarboxylic anhydride, tetracyclo[6.2.1.1^{3,6}.0^{2,7}]dodec-4-ene-9,10-dicarboxylic anhydride, hexacyclo[10.2.1.1^{3,10}.1^{5,8}.0^{2,11}.0^{4,9}]heptadec-6-ene-13,14-dicarboxylic anhydride, and other alicyclic olefins which have carboxylic anhydride groups; 9-methyl-9-methoxycarbonyltetracyclo[6.2.1.1^{3,6}.0^{2,7}]dodec-4-ene, 5-methoxycarbonyl-bicyclo[2.2.1]hept-2-ene, 5-methyl-5-methoxycarbonyl-bicyclo[2.2.1]hept-2-ene, and other alicyclic olefins which have carboxylic acid ester groups; (5-(4-hydroxyphenyl)bicyclo[2.2.1]hept-2-ene, 9-(4-hydroxyphenyl)tetracyclo[6.2.1.1^{3,6}.0^{2,7}]dodec-4-ene, N-(4-hydroxyphenyl)bicyclo[2.2.1]hept-5-ene-2,3-dicarboxyimide, and other alicyclic olefins which have phenolic hydroxyl groups etc. may be mentioned. These may be used alone or may be used in two or more types.

As specific examples of the alicyclic olefin which does not have epoxy reactive groups, bicyclo[2.2.1]hept-2-ene (common name: norbornene), 5-ethyl-bicyclo[2.2.1]hept-2-ene, 5-butyl-bicyclo[2.2.1]hept-2-ene, 5-ethylidene-bicyclo[2.2.1]hept-2-ene, 5-methylidene-bicyclo[2.2.1]hept-2-ene, 5-vinyl-bicyclo[2.2.1]hept-2-ene, tricyclo[5.2.1.0^{2,6}]deca-3,8-diene (common name: dicyclopentadiene), tetracyclo[6.2.1.1^{3,6}.0^{2,7}]dodec-4-ene (common name: tetracyclododecene), 9-methyl-tetracyclo[6.2.1.1^{3,6}.0^{2,7}]dodec-4-ene, 9-ethyl-tetracyclo[6.2.1.1^{3,6}.0^{2,7}]dodec-4-ene, 9-methylidenete-tetracyclo[6.2.1.1^{3,6}.0^{2,7}]dodec-4-ene, 9-ethylidene-tetracyclo[6.2.1.1^{3,6}.0^{2,7}]dodec-4-ene, 9-methoxycarbonyl-tetracyclo [6.2.1.1^{3,6}.0^{2,7}]dodec-4-ene, 9-vinyltetracyclo[6.2.1.1^{3,6}.0^{2,7}]dodec-4-ene, 9-propenyl-tetracyclo[6.2.1.1^{3,6}.0^{2,7}]dodec-4-ene, 9-phenyl-tetracyclo[6.2.1.1^{3,6}.0^{2,7}]dodec-4-ene, tetracyclo[9.2.1.0^{2,10}.0^{3,8}]tetradeca-3,5,7,12-tetraene, cyclopentene, cyclopentadiene, etc. may be mentioned. These may be used alone or may be used in two or more types.

As examples of the aromatic olefin which does not have epoxy reactive groups, styrene, α-methylstyrene, divinylbenzene, etc. may be mentioned. These may be used alone or may be used in two or more types.

As monomer which has epoxy reactive groups which can be copolymerized with alicyclic olefins or aromatic olefins and are other than alicyclic olefins which have epoxy reactive groups, ethylenically unsaturated compounds which have epoxy reactive groups may be mentioned. As specific examples, an acrylic acid, methacrylic acid, α-ethylacrylic acid, 2-hydroxyethyl (meth)acrylic acid, maleic acid, fumaric acid, itaconic acid, and other unsaturated carboxylic acid compounds; maleic anhydride, butenyl succinic anhydride, tetrahydrophthalic anhydride, citraconic anhydride, and other unsaturated carboxylic anhydrides; etc. may be mentioned. These may be used alone or may be used in two or more types.

As monomer which does not have epoxy reactive groups which can be copolymerized with alicyclic olefins or aromatic olefins and are other than alicyclic olefins, ethylene or α-olefins having 2 to 20 carbon atoms such as ethylenically unsaturated compounds which do not have epoxy reactive groups may be mentioned. As specific examples of these, ethylene, propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, 1-eicosene; 1,4-hexadiene, 4-methyl-1,4-hexadiene, 5-methyl-1,4-hexadiene, 1,7-octadiene, and other unconjugated dienes; etc. may be mentioned. These may be used alone or may be used in two or more types.

The molecular weight of the alicyclic olefin polymer (A4) used in the present invention is not particularly limited, but the weight average molecular weight converted to polystyrene which is measured by gel permeation chromatography using tetrahydrofuran as a solvent is preferably 500 to 1,000,000 in range, more preferably 1,000 to 500,000 in range, particularly preferably 3,000 to 300,000 in range. If the weight average molecular weight is too small, the cured article obtained by curing the resin composition falls in mechanical strength, while if too large, the workability tends to deteriorate when formed into a sheet shape or film shape to obtain a shaped article.

As the polymerization catalyst in the case of obtaining the alicyclic olefin polymer (A1) used in the present invention by ring opening polymerization, a conventionally known metathesis polymerization catalyst can be used. As the metathesis polymerization catalyst, a transition metal compound which contains atoms of Mo, W, Nb, Ta, Ru, etc. may be illustrated. Among these, compounds which contain Mo, W, or Ru are high in polymerization activity and therefore preferred. As specific examples of particularly preferable metathesis polymerization catalysts, (1) catalysts which include, as main catalysts, molybdenum or tungsten compounds which has halogen groups, imide groups, alkoxyl groups, allyloxy groups, or carbonyl groups as ligands and include organometallic compounds as second ingredients and (2) metal carbene complex catalysts which have Ru as the central metal may be mentioned.

As examples of compounds which are used as the main catalysts in the catalysts of the above (1), MoCl₅, MoBr₅, and other halogenated molybdenum compounds and WCl₆, WOCl₄, tungsten(phenylimide)tetrachloride diethyl ether and other halogenated tungsten compounds may be mentioned. Further, as the organometallic compounds which are used as the second ingredients in the catalyst of the above (1), organometallic compounds of Group I, Group II, Group XII, Group XIII, or Group XIV of the Periodic Table may be mentioned. Among these, organolithium compounds, organomagnesium compounds, organozinc compounds, organoaluminum compounds, and organotin compounds are preferable, while organolithium compounds, organoaluminum compounds, and organotin compounds are particularly preferable. As organolithium compounds, n-butyllithium, methyllithium, phenyllithium, neopentyllithium, neophyllithium, etc. may be mentioned. As organomagnesium compounds, butylethylmagnesium, butyloctylmagnesium, dihexylmagnesium, ethylmagnesium chloride, n-butylmagnesium chloride, allylmagnesium bromide, neopentylmagnesium chloride, neophylmagnesium chloride, etc. may be mentioned. As organozinc compounds, dimethylzinc, diethylzinc, diphenylzinc, etc. may be mentioned. As organoaluminum compounds, trimethylaluminum, triethylaluminum, triisobutylaluminum, diethylaluminum chloride, ethylaluminum sesquichloride, ethylaluminum dichloride, diethylaluminum ethoxide, ethylaluminum diethoxide, etc. may be mentioned. Furthermore, it is possible to use aluminoxane compounds which are obtained by reaction of these organoaluminum compounds and water. As organotin compounds, tetramethyltin, tetra(n-butyl)tin, tetraphenyltin, etc. may be mentioned. The amounts of these organometallic compounds differ depending on the organometallic compounds used, but by molar ratio with respect to the central metal of the main catalyst, 0.1 to 10,000 times is preferable, 0.2 to 5,000 times is more preferable, and 0.5 to 2,000 times is particularly preferable.

Further, as the metal carbene complex catalyst having Ru as a central metal in the above (2), (1,3-dimesitylimidazolidin-2-ylidene) (tricyclohexylphosphine)benzylideneruthenium dichloride, bis(tricyclohexylphosphine)benzylideneruthenium dichloride, tricyclohexylphosphine-[1,3-bis(2,4,6-trimethylphenyl)-4,5-dibromoimidazol-2-ylidene]-[benzylidene]ruthenium dichloride, 4-acetoxybenzylidene(dichloro)(4,5-dibromo-1,3-dimesityl-4-imidazolin-2-ylidene)(tricyclohexylphosphine)ruthenium, etc. may be mentioned.

The ratio of use of the metathesis polymerization catalyst is, by molar ratio with respect to the monomers which are used for the polymerization (transition metal in metathesis polymerization catalyst:monomers), usually 1:100 to 1:2,000,000 in range, preferably 1:200 to 1:1,000,000 in range. If the amount of the catalyst is too great, the removal of the catalyst becomes difficult, while if too small, a sufficient polymerization activity is liable to be unable to be obtained.

The polymerization reaction is usually performed in an organic solvent. The organic solvent which is used is not particularly limited so long as the polymer dissolves or disperses under predetermined conditions and the solvent does not affect the polymerization, but one which is generally used industrially is preferable. As specific examples of the organic solvent, pentane, hexane, heptane, and other aliphatic hydrocarbons; cyclopentane, cyclohexane, methyl cyclohexane, dimethylcyclohexane, trimethylcyclohexane, ethylcyclohexane, diethylcyclohexane, decahydronaphthalene, bicycloheptane, tricyclodecane, hexahydroindene, cyclooctane, and other aliphatic hydrocarbons; benzene, toluene, xylene, and other aromatic hydrocarbons; dichloromethane, chloroform, 1,2-dichloroethane, and other halogen-containing aliphatic hydrocarbons; chlorobenzene, dichlorobenzene, and other halogen-containing aromatic hydrocarbons; nitromethane, nitrobenzene, acetonitrile, and other nitrogen-containing hydrocarbons; diethyl ether, tetrahydrofuran, and other ethers; anisole, phenetol, and other aromatic ethers; etc. may be mentioned. Among these as well, the industrially generally used aromatic hydrocarbons and aliphatic hydrocarbons, alicyclic hydrocarbons, ethers, and aromatic ethers are preferable.

The use amount of the organic solvent is preferably an amount which gives a concentration of the monomers in the polymerization solution of 1 to 50 wt %, more preferably 2 to 45 wt %, particularly preferably 3 to 40 wt %. If the concentration of the monomers is less than 1 wt %, the productivity becomes poor, while if over 50 wt %, the solution after polymerization becomes too high in viscosity and the subsequent hydrogenation reaction sometimes becomes difficult.

The polymerization reaction is started by mixing the monomers which are used for the polymerization and the metathesis polymerization catalyst. As the method for mixing these, the metathesis polymerization catalyst solution may be added to the monomer solution or vice versa. When the metathesis polymerization catalyst which is used is a mixed catalyst of a main catalyst constituted by a transition metal compound and a second ingredient constituted by an organometallic compound, the reaction solution of the mixed catalyst may be added to the monomer solution or vice versa. Further, a solution of the transition metal compound may be added to a mixed solution of the monomers and organometallic compound or vice versa. Furthermore, an organometallic compound may be added to a mixed solution of the monomers and a transition metal compound or vice versa.

The polymerization temperature is not particularly limited, but is usually −30° C. to 200° C., preferably 0° C. to 180° C. The polymerization time is not particularly limited, but is usually 1 minute to 100 hours.

As the method of adjusting the molecular weight of the obtained alicyclic olefin polymer, the method of adding a suitable amount of a vinyl compound or diene compound may be mentioned. The vinyl compound which is used for adjustment of the molecular weight is not particularly limited so long as an organic compound which has vinyl groups, but 1-butene, 1-pentene, 1-hexene, 1-octene, and other α-olefins; styrene, vinyltoluene, and other styrenes; ethylvinyl ether, i-butylvinyl ether, allylglycidyl ether, and other ethers; allylchloride and other halogen-containing vinyl compounds; allyl acetate, allyl alcohol, glycidyl methacrylate, and other oxygen-containing vinyl compounds, acrylamide and other nitrogen-containing vinyl compounds, etc. may be mentioned. As the diene compounds which are used for adjustment of the molecular weight, 1,4-pentadiene, 1,4-hexadiene, 1,5-hexadiene, 1,6-heptadiene, 2-methyl-1,4-pentadiene, 2,5-dimethyl-1,5-hexadiene, and other unconjugated dienes or 1,3-butadiene, 2-methyl-1,3-butadiene, 2,3-dimethyl-1,3-butadiene, 1,3-pentadiene, 1,3-hexadiene, and other conjugated dienes may be mentioned. The amount of addition of the vinyl compound or diene compound may be freely selected, in accordance with the molecular weight which is targeted, from 0.1 to 10 mol %.

As the polymerization catalyst when obtaining the alicyclic olefin polymer (A4) used in the present invention by addition polymerization, for example, a catalyst which is comprised of a titanium, zirconium, or vanadium compound and an organoaluminum compound may be suitably used. These polymerization catalysts can be used alone or as two or more types combined. The amount of the polymerization catalyst is, by molar ratio of the metal compound in the polymerization catalyst:monomers which are used for the polymerization, usually 1:100 to 1:2,000,000 in range.

When using a hydrogenated product of a ring-opening polymer as the alicyclic olefin polymer (A4) used in the present invention, the hydrogenation of the ring-opening polymer is usually performed by using a hydrogenation catalyst. The hydrogenation catalyst is not particularly limited, but one which is generally used at the time of hydrogenation of an olefin compound may be suitably employed. As specific examples of a hydrogenation catalyst, for example, a Ziegler catalyst which is comprised of a combination of a transition metal compound and an alkali metal compound such as cobalt acetate and triethylaluminum, nickel acetyl acetonate and triisobutylaluminum, titanocene dichloride and n-butyllithium, zirconocene dichloride and sec-butyllithium, and tetrabutoxytitanate and dimethylmagnesium; dichlorotris(triphenylphosphine)rhodium, the ones which are described in Japanese Patent Publication No. 7-2929A, Japanese Patent Publication No. 7-149823A, Japanese Patent Publication No. 11-209460A, Japanese Patent Publication No. 11-158256A, Japanese Patent Publication No. 11-193323A, Japanese Patent Publication No. 11-209460A, etc., precious metal complex catalysts comprised of bis(tricyclohexylphosphine)benzylidyneruthenium (IV)dichloride and other ruthenium compounds; and other homogeneous catalysts may be mentioned. Further, heterogeneous catalysts of nickel, palladium, platinum, rhodium, ruthenium, and other metals carried on a carbon, silica, diatomaceous earth, alumina, titanium oxide, and other carrier, for example, nickel/silica, nickel/diatomaceous earth, nickel/alumina, palladium/carbon, palladium/silica, palladium/diatomaceous earth, palladium/alumina, etc., may also be used. Further, the above-mentioned metathesis polymerization catalysts may also be used as they are as hydrogenation catalysts.

The hydrogenation reaction is usually performed in an organic solvent. The organic solvent may be suitably selected in accordance with the solubility of the hydrogenated product which is produced. An organic solvent similar to the organic solvent which is used in the above-mentioned polymerization reaction may be used. Therefore, after the polymerization reaction, there is no need to replace the organic solvent. It is possible to add a hydrogenation catalyst for a reaction as is. Furthermore, among the organic solvents which are used for the above-mentioned polymerization reaction, from the viewpoint of their not reacting at the time of the hydrogenation reaction, an aromatic hydrocarbons, aliphatic hydrocarbons, alicyclic hydrocarbons, ethers, or aromatic ethers is preferable, while an aromatic ether is more preferable.

The hydrogenation reaction conditions may be suitably selected in accordance with the type of the hydrogenation catalyst which is used. The reaction temperature is usually −20 to 250° C., preferably −10 to 220° C., more preferably 0 to 200° C. If lower than −20° C., the reaction velocity becomes slow, while conversely if higher than 250° C., secondary reactions easily occur. The pressure of the hydrogen is usually 0.01 to 10.0 MPa, preferably 0.05 to 8.0 MPa. If the hydrogen pressure is lower than 0.01 MPa, the hydrogenation reaction velocity becomes slow, while if higher than 10.0 MPa, a high pressure resistant reaction apparatus becomes necessary.

The time of the hydrogenation reaction is suitably selected for controlling the hydrogenation rate. The reaction time is usually 0.1 to 50 hours in range. It is possible to hydrogenate 50 mol % or more of the carbon-carbon double bonds of the mainchain in the polymer, preferably 70 mol % or more, more preferably 80 mol % or more, particularly preferably 90 mol % or more.

After performing the hydrogenation reaction, it is possible to perform processing to remove the catalyst which is used for the hydrogenation reaction. The method of removal of the catalyst is not particularly limited. Centrifugation, filtration, or other methods may be mentioned. Furthermore, it is possible to add water, alcohol, or another catalyst deactivator or add active clay, alumina, diatomaceous earth, or another adsorbent so as to promote removal of the catalyst.

The alicyclic olefin polymer (A4) used in the present invention may be used as the polymer solution after polymerization or the hydrogenation reaction or may be used after removal of the solvent, but since dissolution or dispersion of the additives becomes better when preparing the resin composition and since the process can be simplified, use as a polymer solution is preferable.

The amount of the alicyclic olefin polymer (A4) in the curable resin composition of the present invention is 2 to 50 parts by weight with respect to 100 parts by weight of the epoxy compound (A1), preferably 5 to 45 parts by weight, furthermore preferably 10 to 40 parts by weight in range. If the amount of the alicyclic olefin polymer (A4) is too small, the heat resistance and low linear expansion property when made into a cured article tend to fall, while if too great, the resin fluidity of the curable resin composition tends to fall, the wire embedding flatness tend to deteriorate, and the heat resistance and low linear expansion property when made into a cured article tend to fall.

Further, in the curable resin composition of the present invention, the ratio of the epoxy groups of the epoxy compound (A1) and the active ester groups of the active ester compound (A2) and the epoxy reactive groups of the alicyclic olefin polymer (A4) is preferably, by equivalent ratio of the “epoxy groups/(active ester groups+epoxy reactive groups)”, 0.8 to 1.2 in range, more preferably 0.85 to 1.15 in range, more preferably 0.9 to 1.1 in range. By making the equivalent ratio of the “epoxy groups/(active ester groups+epoxy reactive groups)” in the above range, it is possible to improve the heat resistance and linear expansion coefficient when made into a cured article.

(Other Ingredients)

Further, the curable resin composition of the present invention may contain a curing accelerator in accordance with need. The curing accelerator is not particularly limited, but for example an aliphatic polyamine, aromatic polyamine, secondary amine, tertiary amine, acid anhydride, imidazole derivative, organic acid hydrazide, dicyan diamide and its derivatives, urea derivatives, etc. may be mentioned, but among these, an imidazole derivative is particularly preferable.

The imidazole derivative is not particularly limited so long as it is a compound which has an imidazole structure, but, for example, 2-ethylimidazole, 2-ethyl-4-methylimidazole, bis-2-ethyl-4-methylimidazole, 1-methyl-2-ethylimidazole, 2-isopropylimidazole, 2,4-dimethylimidazole, 2-heptadecylimidazole, and other alkyl substituted imidazole compounds; 2-phenylimidazole, 2-phenyl-4-methylimidazole, 1-benzyl-2-methylimidazole, 1-benzyl-2-ethylimidazole, 1-benzyl-2-phenylimidazole, benzimidazole, 2-ethyl-4-methyl-1-(2′-cyanoethyl)imidazole, and other imidazole compounds which are substituted by hydrocarbon groups which contain ring structures such as aryl groups or aralkyl groups etc. may be mentioned. These may be used as single type alone or as two or more types combined.

The amount when mixing in a curing accelerator may be suitably selected in accordance with the purpose of use, but is preferably 0.1 to 10 parts by weight with respect to 100 parts by weight of the epoxy compound (A1), more preferably 0.5 to 8 parts by weight, furthermore preferably 0.5 to 6 parts by weight, still furthermore preferably 3 to 5 parts by weight.

Furthermore, the curable resin composition of the present invention may have mixed into it, for the purpose of improving the flame retardance when made into a cured article, for example, a halogen-containing flame retardant or phosphoric acid ester flame retardant or other general flame retardant which is mixed into a resin composition for forming an electrical insulating film. The amount when mixing a flame retardant into the curable resin composition of the present invention is preferably 100 parts by weight or less with respect to 100 parts by weight of the epoxy compound (A1), more preferably 60 parts by weight or less.

Further, the curable resin composition used in the present invention may contain, furthermore, in accordance with need, a flame retardant aid, heat resistance stabilizer, weather resistance stabilizer, antiaging agent, UV absorber (laser processing enhancing agent), leveling agent, antistatic agent, slip agent, antiblocking agent, anticlouding agent, lubricant, dye, natural oil, synthetic oil, wax, emulsifying agent, magnetic material, dielectric characteristic adjuster, toughening agent, or other ingredient. The ratios of these optional ingredients added may be suitably selected in a range not detracting from the object of the present invention.

The method of production of the curable resin composition used in the present invention is not particularly limited. The above ingredients may be mixed as they are or may be mixed in the state dissolved or dispersed in an organic solvent. Part of the ingredients may be dissolved or dispersed in an organic solvent to prepare a composition and the remaining ingredients may be mixed into that composition.

(Film)

The film of the present invention is a shaped article obtained by forming the above-mentioned curable resin composition of the present invention into a sheet shape or film shape.

When forming the curable resin composition of the present invention into a sheet shape or film shape to obtain a shaped article, it is preferable to obtain it by coating, spraying, or casting the curable resin composition of the present invention while, in accordance with need, adding an organic solvent, then drying.

As the support which is used at this time, a resin film or metal foil etc. may be mentioned. As the resin film, a polyethylene terephthalate film, polypropylene film, polyethylene film, polycarbonate film, polyethylene naphthalate film, polyacrylate film, nylon film, etc. may be mentioned. Among these films, from the viewpoint of the heat resistance, chemical resistance, peel property, etc., a polyethylene terephthalate film or polyethylene naphthalate film is preferable. As the metal foil, a copper foil, aluminum foil, nickel foil, chromium foil, gold foil, silver foil, etc. may be mentioned.

The thickness of the sheet shape or film shape shaped article is not particularly limited, but from the viewpoint of the work efficiency etc., it is usually 1 to 150 μm, preferably 2 to 100 μm, more preferably 5 to 80

As the method of coating the curable resin composition of the present invention, dip coating, roll coating, curtain coating, die coating, slit coating, gravure coating, etc. may be mentioned.

Note that, in the present invention, as the sheet shape or film shape shaped article, the curable resin composition of the present invention is preferably in an uncured or semicured state. Here, “uncured” means the state where when dipping a shaped article in a solvent which is able to dissolve the epoxy compound (A1), substantially all of the epoxy compound (A1) are dissolved. Further, “semicured” means the state of being partially cured to an extent enabling further curing upon heating, preferably a state where parts of the epoxy compound (A1) (specifically, amounts of 7 wt % or more and amounts where parts remain) is dissolved in a solvent able to dissolve the epoxy compound (A1) or a state where the volume after dipping the shaped article in the solvent for 24 hours is 200% or more of the volume before dipping (swelling rate).

Further, the curable resin composition of the present invention may be coated on a support, then dried if necessary. The drying temperature is preferably made a temperature of an extent whereby the curable resin composition of the present invention does not cure. It is usually 20 to 300° C., preferably 30 to 200° C. If the drying temperature is too high, the curing reaction proceeds too much and the obtained shaped article is liable to no longer become the uncured or semicured state. Further, the drying time is usually 30 seconds to 1 hour, preferably 1 minute to 30 minutes.

The film of the present invention obtained in this way is used in the state attached to the support or peeled off from the support.

Further, in the present invention, the film of the present invention may be made a laminated film which has an adhesive layer which is comprised of the curable resin composition of the present invention and a plateable layer which is comprised of the later explained plateable layer-use resin composition.

In this case, the plateable layer-use resin composition which is used to form the plateable layer is not particularly limited, but one which has an alicyclic olefin polymer (B1) which has a polar group and a curing agent (B2) is preferable.

The alicyclic olefin polymer (B1) which has a polar group (below, suitably abbreviated as an “alicyclic olefin polymer (B1)”) is not particularly limited. One which has an alicyclic structure constituted by a cycloalkane structure or cycloalkene structure etc. may be mentioned, but from the viewpoint of the mechanical strength, heat resistance, etc., one which has a cycloalkane structure is preferable. Further, as the polar group which is contained in the alicyclic olefin polymer (B1), it is possible to use one similar to epoxy reactive group which is contained in the alicyclic olefin polymer (A4) which forms the above-mentioned curable resin composition of the present invention and therefore as the alicyclic olefin polymer (B1), it is possible to use one similar to the alicyclic olefin polymer (A4) which forms the above-mentioned curable resin composition of the present invention.

The curing agent (B2) used in the present invention is not particularly limited so long as able to form a cross-linked structure in the alicyclic olefin polymer (B1) by heating. It is possible to use a curing agent which is mixed in a resin composition for use in forming a general electrical insulating film. As the curing agent (B2), it is preferable to use a compound which has two or more functional groups which can form bonds by reaction with the polar groups of the used alicyclic olefin polymer (B1) as the curing agent.

For example, as the curing agent which is suitably used when using an alicyclic olefin polymer (B1) which has a carboxyl group, carboxylic anhydride group, or phenolic hydroxy group as the alicyclic olefin polymer (B1), a polyepoxy compound, polyisocyanate compound, polyamine compound, polyhydrazide compound, aziridine compound, basic metal oxides, organometallic halide, etc. may be mentioned. These may be used alone or may be used in two or more types. Further, it is also possible to jointly use these compounds and peroxides as a curing agent.

As the polyepoxy compound, for example, a phenol novolac type epoxy compound, cresol novolac type epoxy compound, cresol type epoxy compound, bisphenol A type epoxy compound, bisphenol F type epoxy compound, hydrogenated bisphenol A type epoxy compound, or other glycidyl ether type epoxy compound; alicyclic epoxy compound, glycidyl ester type epoxy compound, glycidyl amine type epoxy compound, fluorine based epoxy compound, polyfunctional epoxy compound, isocyanulate type epoxy compound, phosphorus-containing epoxy compound, or other polyepoxy compound; or other compound which has two or more epoxy groups in its molecule may be mentioned. These may be used alone or may be used in two or more types.

As the polyisocyanate compound, C₆ to C₂₄ diisocyanates and triisocyanates are preferable. As examples of the diisocyanates, 2,4-tolylene diisocyanate, 2,6-tolylene diisocyanate, 4,4′-diphenylmethane diisocyanate, hexamethylene diisocyanate, p-phenylene diisocyanate, etc. may be mentioned. As examples of triisocyanates, 1,3,6-hexamethylene triisocyanate, 1,6,11-undecane triisocyanate, bicycloheptane triisocyanate, etc. may be mentioned. These may be used alone or may be used in two or more types.

As the polyamine compound, a C₄ to C₃₀ aliphatic polyamine compound which has two or more amino groups, aromatic polyamine compound, etc. may be mentioned. Ones, like guanidine compounds, which have unconjugated nitrogen-carbon double bonds are not included. As the aliphatic polyamine compound, a hexamethylenediamine, N′,N′-dicinnamylidene-1,6-hexane diamine etc. may be mentioned. As the aromatic polyamine compound, 4,4′-methylenedianiline, m-phenylene diamine, 4,4′-diaminodiphenyl ether, 4′-(m-phenylene diisopropylidene)dianiline, 4,4′-(p-phenylenediisopropylidene)dianiline, 2,2′-bis[4-(4-aminophenoxy)phenyl]propane, 1,3,5-benzenetriamine, etc. may be mentioned. These may be used alone or may be used in two or more types.

As examples of polyhydrazide compounds, isophthalic acid dihydrazide, terephthalic acid dihydrazide, 2,6-naphthalenedicarboxylic acid dihydrazide, maleic acid dihydrazide, itaconic acid dihydrazide, trimellitic acid dihydrazide, 1,3,5-benzenetricarboxylic acid dihydrazide, pyromellitic acid dihydrazide, etc. may be mentioned. These may be used alone or may be used in two or more types.

As aziridine compounds, tris-2,4,6-(1-aziridinyl)-1,3,5-triazine, tris[1-(2-methyl)aziridinyl]phosphinoxide, hexa[1-(2-methyl)aziridinyl]triphosphatriazine, etc. may be mentioned. These may be used alone or may be used in two or more types.

Among the above-mentioned curing agents, from the viewpoint of the reactivity with the polar groups of the alicyclic olefin polymer (B1) being mild and the ease of handling of the plateable layer-use resin composition, polyepoxy compounds are preferable, while glycidyl ether type epoxy compounds and alicyclic polyepoxy compounds are particularly preferably used.

The amount of the curing agent (B2) in the plateable layer-use resin composition is preferably 1 to 1000 parts by weight with respect to 100 parts by weight of the alicyclic olefin polymer (B1), more preferably 5 to 800 parts by weight, furthermore preferably 10 to 700 parts by weight in range. By making the amount of the curing agent (B2) in the above range, it is possible to make the cured article which is obtained by curing the laminated film excellent in mechanical strength and electrical properties, so this is preferred.

Further, the plateable layer-use resin composition used in the present invention may contain a hindered phenol compound or hindered amine compound in addition to the above ingredients.

The hindered phenol compound is a phenol compound which has at least one hindered structure which has a hydroxyl group and which does not have a hydrogen atom at the carbon atom of the p-position of the hydroxyl group in its molecule.

As specific examples of the hindered phenol compound, 1,1,3-tris-(2-methyl-4-hydroxy-5-tert-butylphenyl)butane, 4,4′-butylidenebis-(3-methyl-6-tert-butylphenol), 2,2-thiobis(4-methyl-6-tert-butylphenol), n-octadecyl-3-(4′-hydroxy-3′,5′-di-tert-butylphenyl)propionate, tetrakis-[methylene-3-(3′,5′-di-tert-butyl-4′-hydroxyphenyl)propionate]methane, pentaerythritol-tetrakis[3-(3,5-di-tert-butyl-4-hydroxyphenyl)propionate], triethyleneglycol-bis[3-(3-tert-butyl-5-methyl-4-hydroxyphenyl)propionate], 1,6-hexanediol-bis[3-(3,5-di-tert-butyl-4-hydroxyphenyl)propionate], 2,4-bis(n-octylthio)-6-(4-hydroxy-3,5-di-tert-butylanilino)-1,3,5-triazine, tris-(3,5-di-tert-butyl-4-hydroxybenzyl)-isocyanulate, 2,2-thio-diethylenebis[3-(3,5-di-tert-butyl-4-hydroxyphenyl)propionate], N,N′-hexamethylenebis(3,5-di-tert-butyl-4-hydroxy-hydrocinnamide, 2,4-bis[(octylthio)methyl]-o-cresol, bis(3,5-di-tert-butyl-4-hydroxybenzyl phosphonic acid ethyl)calcium, 3,5-di-tert-butyl-4-hydroxybenzyl-phosphonate-diethyl ester, tetrakis[methylene (3,5-di-tert-butyl-4-hydroxycinnamate)]methane, octadecyl-3-(3,5-di-tert-butyl-4-hydroxyphenyl)propionic acid ester, hindered bisphenol, etc. may be mentioned.

The amount of the hindered phenol compound in the plateable layer-use resin composition is not particularly limited, but it is preferably 0.04 to 10 parts by weight with respect to 100 parts by weight of the alicyclic olefin polymer (B1), more preferably 0.3 to 5 parts by weight, furthermore preferably 0.5 to 3 parts by weight in range. By making the amount of the hindered phenol compound in the above range, it is possible to make the cured article which is obtained by curing the laminated film excellent in mechanical strength.

Further, a hindered amine compound is a compound which has at least one 2,2,6,6-tetraalkylpiperidine group which has a secondary amine or tertiary amine at the 4-position in its molecule. The number of carbons of the alkyl is usually 1 to 50. As the hindered amine compound, a compound which has at least one 2,2,6,6-tetramethylpiperidyl group which has a secondary amine or tertiary amine at the 4-position in its molecule is preferable. Note that, in the present invention, it is preferable to use both the hindered phenol compound and the hindered amine compound. By using these together, when treating the cured article which is obtained by curing a laminated film to roughen its surface by using an aqueous solution of permanganate etc., even when the surface roughening treatment conditions change, it becomes possible to keep the cured article after surface roughening treatment as one low in surface roughness.

As specific examples of the hindered amine compound, bis(2,2,6,6-tetramethyl-4-piperidyl)sebacate, bis(1,2,2,6,6-pentamethyl-4-piperidyl)sebacate, 1-[2-{3-(3,5-di-tert-butyl-4-hydroxyphenyl)propionyloxy}ethyl]-4-{3-(3,5-di-tert-butyl-4-hydroxyphenyl)propionyloxy}-2,2,6,6-tetramethylpiperidine, 8-benzyl-7,7,9,9-tetramethyl-3-octyl-1,2,3-triazaspiro[4,5]undecane-2,4-dione, 4-benzyloxy-2,2,6,6-tetramethylpiperidine, dimethyl succinate-2-(2-hydroxyethyl)-4-hydroxy-2,2,6,6-tetramethylpiperidine polycondensate, poly[[6-(1,1,3,3-tetramethylbutyl)imino-1,3,5-triazin-2,4-dyl][(2,2,6,6-tetramethyl-4-piperidyl)imino]hexamethylene[[2,2,6,6-tetramethyl-4-piperidyl)imino]], poly[(6-morpholino-s-triazin-2,4-dyl)[2,2,6,6-tetramethyl-4-piperidyl)imino]-hexamethylene[(2,2,6,6-tetramethyl-4-piperidyl)imino]], 2-(3,5-di-tert-butyl-4-hydroxybenzyl)-2-n-butylmalonic acid bis(1,2,2,6,6-pentamethyl-4-piperidyl), tetrakis(1,2,2,6,6-pentamethyl-4-piperidyl)1,2,3,4-butanetetracarboxylate, tetrakis(2,2,6,6-tetramethyl-4-piperidyl)1,2,3,4-butanetetracarboxylate, condensate of 1,2,3,4-butanetetracarboxylic acid, 1,2,2,6,6-pentamethyl-4-piperidinol and tridecyl alcohol, condensate of 1,2,3,4-butanetetracarboxylic acid, 2,2,6,6-tetramethyl-4-piperidinol and tridecyl alcohol, condensate of 1,2,3,4-butanetetracarboxylic acid, 1,2,2,6,6-pentamethyl-4-piperidinol and β,β,β′,β′-tetramethyl-3,9-(2,4,8,10-tetraoxaspiro[5,5]undecane)diethanol, condensate of N,N′-bis(3-aminopropyl)ethylenediamine and 2,4-bis[N-butyl-N-(1,2,2,6,6-pentamethyl-4-piperidyl)amino]-6-chloro-1,3,5-triazine, 1,2,2,6,6-tetramethyl-4-piperidyl-methacrylate, 2,2,6,6-tetramethyl-4-piperidyl-methacrylate, methyl-3-[3-tert-butyl-5-(2H-benzotriazol-2-yl)-4-hydroxyphenyl]propionate-polyethylene glycol, etc. may be mentioned.

The amount of the hindered amine compound is not particularly limited, but is normally 0.02 to 10 parts by weight with respect to 100 parts by weight of the alicyclic olefin polymer (B1), preferably 0.2 to 5 parts by weight, more preferably 0.25 to 3 parts by weight in range. By making the amount of the hindered amine compound in the above range, it is possible to make the cured article which is obtained by curing the laminated film excellent in mechanical strength.

Further, the plateable layer-use resin composition used in the present invention may contain a curing accelerator in addition to the above ingredients. As the curing accelerator, a curing accelerator which is mixed into a general resin composition for electrical insulating film forming use may be used, but, for example, a curing accelerator similar to the above-mentioned curable resin composition of the present invention may be used. The amount of the curing accelerator in the plateable layer-use resin composition may be suitably selected in accordance with the purpose of use, but is preferably 0.001 to 30 parts by weight with respect to 100 parts by weight of the alicyclic olefin polymer (B1), more preferably 0.01 to 10 parts by weight, furthermore preferably 0.03 to 5 parts by weight.

Furthermore, the plateable layer-use resin composition used in the present invention may contain a filler in addition to the above ingredients. As the filler, it is possible to use one similar to the filler (A3) which forms the curable resin composition of the present invention. The amount of the filler in the plateable layer-use resin composition is 1 to 70 wt % with respect to the plateable layer-use resin composition as a whole, preferably 2 to 50 wt %, more preferably 3 to 30 wt %.

Further, the plateable layer-use resin composition used in the present invention may further have mixed into it, other than the above ingredients and in the same way as the curable resin composition of the present invention, a curing accelerator, flame retardant, flame retardant aid, heat resistance stabilizer, weather resistance stabilizer, antiaging agent, UV absorber (laser processing enhancing agent), leveling agent, antistatic agent, slip agent, antiblocking agent, anticlouding agent, lubricant, dye, natural oil, synthetic oil, wax, emulsifying agent, magnetic material, dielectric characteristic adjuster, toughening agent, or another other ingredient. The ratios of these optional ingredients added may be suitably selected in a range not detracting from the object of the present invention.

The method of production of the plateable layer-use resin composition used in the present invention is not particularly limited. The above ingredients may be mixed as they are or may be mixed in a state dissolved or dispersed in an organic solvent or part of the above ingredients may be dissolved or dispersed in an organic solvent to prepare a composition and the remaining ingredients may be mixed in the composition.

When making the film of the present invention a laminated film which has an adhesive layer which is comprised of the curable resin composition of the present invention and the plateable layer which is comprised of the plateable layer-use resin composition, the laminated film can be produced, for example, by the following two methods: (1) the method of coating, spraying, or casting the above-mentioned plateable layer-use resin composition on a support and, if necessary, drying it, then further coating or casting the above-mentioned curable resin composition of the present invention on it and, if necessary, drying it and (2) the method of laminating a plateable layer-use shaped article obtained by coating, spraying, or casting the above-mentioned plateable layer-use resin composition on a support and, if necessary, drying it to be a sheet shape or film shape and an adhesive layer-use shaped article obtained by coating, spraying, or casting the above-mentioned curable resin composition of the present invention on a support and, if necessary, drying it to be a sheet shape or film shape and joining these shaped articles. Among these methods of production, due to the easier process and the better productivity, the method of production of the above (1) is preferable.

In the method of production of the above-mentioned (1), when coating, spraying, or casting the plateable layer-use resin composition on the support and when coating, spraying, or casting the curable resin composition on the coated, sprayed, or cast plateable layer-use resin composition or, in the method of production of the above-mentioned (2), when shaping the plateable layer-use resin composition and the curable resin composition into sheet shapes or film shapes to obtain the plateable layer-use shaped article and adhesive layer-use shaped article, it is preferable to coat, spray, or cast the plateable layer-use resin composition or the curable resin composition on the support while adding an organic solvent as needed.

As the support which is used at this time, a resin film or metal foil etc. may be mentioned. As the resin film, a polyethylene terephthalate film, polypropylene film, polyethylene film, polycarbonate film, polyethylene naphthalate film, polyarylate film, nylon film, etc. may be mentioned. Among these films, from the viewpoint of the heat resistance, chemical resistance, peel property, etc., a polyethylene terephthalate film or polyethylene naphthalate film is preferable. As the metal foil, copper foil, aluminum foil, nickel foil, chrome foil, gold foil, silver foil, etc. may be mentioned. Note that, the surface roughness Ra of the support is usually 300 nm or less, preferably 150 nm or less, more preferably 100 nm or less.

The thicknesses of the plateable layer-use resin composition and the curable resin composition in the method of production of the above-mentioned (1) and the thicknesses of the plateable layer-use shaped article and adhesive layer-use shaped article in the method of production of the above-mentioned (2) are not particularly limited, but the thickness of the plateable layer when made into a laminated film is preferably 1 to 10 μm, more preferably 1 to 8 μm, furthermore preferably 2 to 5 μm, while the thickness of the adhesive layer is preferably 10 to 100 μm, more preferably 10 to 80 μm, furthermore preferably 15 to 60 μm. If the thickness of the plateable layer is too thin, when forming a conductor layer by electroless plating on a cured article which is obtained by curing the laminated film, the formability of the conductor layer is liable to end up falling, while if the thickness of the plateable layer is too thick, the cured article which is obtained by curing the laminated film is liable to become larger in linear expansion. Further, if the thickness of the adhesive layer is too small, the wire embedding ability of the laminated film is liable to end up falling.

As the method of coating the plateable layer-use resin composition and curable resin composition, dip coating, roll coating, curtain coating, die coating, slit coating, gravure coating, etc. may be mentioned.

Further, in the method of production of the above-mentioned (1), after the plateable layer-use resin composition is coated, sprayed, or cast on the support or after the curable resin composition is coated, sprayed, or cast on the plateable layer-use resin composition or, in the method of production of the above-mentioned (2), after the plateable layer-use resin composition and the curable resin composition are coated on the supports, the compositions may be dried as needed. The drying temperature is preferably made a temperature of an extent where the plateable layer-use resin composition and the curable resin composition will not cure and is normally 20 to 300° C., preferably 30 to 200° C. Further, the drying time is normally 30 seconds to 1 hour, preferably 1 minute to 30 minutes.

Note that, when making the film of the present invention a laminated film which has an adhesive layer which is comprised of the curable resin composition of the present invention and a plateable layer which is comprised of the plateable layer-use resin composition, the plateable layer and adhesive layer which form the laminated film are preferably in the uncured or semicured state. By making these uncured or semicured in state, it is possible to make the adhesive layer which forms the laminated film one which is high in adhesiveness. Here, illustrating the case of use of the alicyclic olefin polymer (B1) as the resin ingredient for forming the plateable layer-use resin composition, “uncured” means the state where when the laminated film is respectively dipped in a solvent which can dissolve the epoxy compound (A1) and a solvent which can dissolve the alicyclic olefin polymer (B1), substantially all of the epoxy compound (A1) and the alicyclic olefin polymer (B1) are dissolved. Further, “semicured” means the state of being partially cured to an extent enabling further curing upon heating, preferably a state where parts of the epoxy compound (A1) and alicyclic olefin polymer (B1) (specifically, amounts of 7 wt % or more and amounts where parts remain) dissolve in respectively a solvent which can dissolve the epoxy compound (A1) and a solvent which can dissolve the alicyclic olefin polymer (B1) or a state where the volume after dipping the shaped article in a solvent for 24 hours is 200% or more of the volume before dipping (swelling rate).

(Prepreg)

The prepreg of the present invention is a composite shaped article obtained by impregnating the above-mentioned curable resin composition of the present invention in a fiber base material and usually has the form of a sheet shape or film shape.

As the fiber base material used in this case, for example, polyamide fiber, polyaramide fiber, polyester fiber, or other organic fiber or glass fiber, carbon fiber, or other inorganic fiber may be mentioned. Further, as the form of the fiber base material, a flat weave or twill weave or other woven fabric or nonwoven fabric etc. may be mentioned. The fiber base material has a thickness of preferably 5 to 100 μm, more preferably 10 to 50 μm. If too thin, the handling becomes difficult, while if too thick, the resin layer becomes relatively thin and its wire embedding ability sometimes becomes insufficient.

Further, the amount of the fiber base material in the prepreg of the present invention is usually 20 to 90 wt %, preferably 30 to 85 wt %.

The method of impregnating the curable resin composition of the present invention in a fiber base material is not particularly limited, but to add an organic solvent to the curable resin composition of the present invention for adjusting the viscosity etc., the method of dipping the fiber base material in the curable resin composition to which the organic solvent is added, the method of coating or spraying the curable resin composition to which an organic solvent is added on a fiber base material, etc. may be mentioned. In the method of coating or spraying, it is possible to place the fiber base material on a support and coat or spray the curable resin composition to which the organic solvent is added on this. Note that, in the prepreg of the present invention, in the same way as the above-mentioned sheet shape or film shape shaped article, it is preferable that the curable resin composition of the present invention be contained in an uncured or semicured state.

Further, after impregnating the curable resin composition of the present invention in the fiber base material, it may be dried in accordance with need. The drying temperature is preferably made a temperature of an extent where the curable resin composition of the present invention does not cure and is usually 20 to 300° C., preferably 30 to 200° C. If the drying temperature is too high, the curing reaction proceeds too much and the obtained prepreg is liable not to become uncured or semicured in state. Further, the drying time is usually 30 seconds to 1 hour, preferably 1 minute to 30 minutes.

Alternatively, in the present invention, the prepreg of the present invention may be made one which is comprised of the above-mentioned laminated film and fiber base material. In this case, the prepreg of the prepreg of the present invention can be made a composite shaped article where one surface of the prepreg is made an adhesive layer which is comprised of the above-mentioned curable resin composition of the present invention and where the other surface is comprised of a plateable layer which is comprised of the above-mentioned plateable layer-use resin composition. In this case as well, as the fiber base material, it is possible to use one the same as that explained above.

Further, when making the prepreg of the present invention one which is comprised of the above-mentioned laminated film and a fiber base material, the method of production is not particularly limited so long as the prepreg of the present invention is one which has an adhesive layer on one surface and has a plateable layer on the other surface and one which has a fiber base material at the inside, but, for example, can be produced by the following methods: (1) the method of stacking a curable resin composition film with support and a plateable layer-use resin composition film with a support to sandwich a fiber base material between them with the resin layer sides of the films facing each other and laminating them as needed under pressure, vacuum, heating, or other conditions; (2) the method of impregnating either the curable resin composition or plateable layer-use resin composition in a fiber base material and drying it as required so as to prepare a prepreg and coating, spraying, or casting the other resin composition on this prepreg or stacking the other resin composition film with a support; or (3) the method of coating, spraying, or casting, either the curable resin composition or plateable layer-use resin composition to a support to form a layer, placing a fiber base material over it, and further coating, spray, or casting the other resin composition over that to form a layer and drying if necessary. Note that, in each method, it is preferable to add an organic solvent to each compositions as required to adjust the viscosities of the compositions and thereby control the workability when impregnating them in the fiber base material or coating, spraying, or casting them on the support. Further, as the method of coating the plateable layer-use resin composition and curable resin composition, dip coating, roll coating, curtain coating, die coating, slit coating, gravure coating, etc. may be mentioned.

As the support which is used at this time, a polyethylene terephthalate film, polypropylene film, polyethylene film, polycarbonate film, polyethylene naphthalate film, polyarylate film, nylon film, or other resin film or copper foil, aluminum foil, nickel foil, chrome foil, gold foil, silver foil, or other metal foil may be mentioned. These may be applied to either just one surface of the prepreg or to both surfaces.

When the prepreg of the present invention is made one which is comprised of the above-mentioned laminated film and a fiber base material, the thickness of the prepreg of the present invention is not particularly limited, but is preferably made a thickness such that the thickness of the plateable layer becomes preferably 1 to 10 μm, more preferably 1.5 to 8 μm, furthermore preferably 2 to 5 μm and, further, the thickness of the adhesive layer becomes preferably 10 to 100 more preferably 10 to 80 μm, furthermore preferably 15 to 60

Further, when making the prepreg of the present invention one comprised of the above-mentioned laminated film and fiber base material, in the same way as the above-mentioned laminated film, the resin composition which forms the plateable layer and adhesive layer is preferably uncured or semicured in state.

The prepreg of the present invention obtained in the above way can be made a cured article by heating and curing it.

The curing temperature is usually 30 to 400° C., preferably 70 to 300° C., more preferably 100 to 200° C. Further, the curing time is 0.1 to 5 hours, preferably 0.5 to 3 hours. The method of heating is not particularly limited. For example, an electric oven etc. may be used for this.

(Laminate)

The laminate of the present invention is one obtained by laminating the above-mentioned film or prepreg of the present invention on a base material. The laminate of the present invention may be one obtained by laminating at least the above-mentioned film or prepreg of the present invention, but is preferably one obtained by laminating a substrate which has a conductor layer on its surface and an electrical insulating layer which is comprised of the film or prepreg of the present invention.

Note that, at this time, when the film of the present invention is a laminated film which has an adhesive layer which is comprised of the curable resin composition of the present invention and a plateable layer which is comprised of a plateable layer-use resin composition or when the prepreg of the present invention is one which is comprised of such a laminated film and fiber base material, it is laminated with the substrate through an adhesive layer. That is, the surface of the electrical insulating layer is made one which is formed by the plateable layer among the plateable layer and adhesive layer of the laminated film or prepreg.

The substrate which has a conductor layer on its surface is one which has a conductor layer on the surface of an electrical insulating substrate. The electrical insulating substrate is formed by curing a resin composition which contains a known electrical insulating material (for example, alicyclic olefin polymer, epoxy resin, maleimide resin, (meth)acrylic resin, diallyl phthalate resin, triazine resin, polyphenyl ether, glass, etc.). The conductor layer is not particularly limited, but is usually a layer which includes wiring which are formed by a conductive metal or other conductor and may further include various circuits as well. The configurations, thicknesses, etc. of the wiring and circuits are not particularly limited. As specific examples of a substrate which has a conductor layer on its surface, a printed circuit board, silicon wafer board, etc. may be mentioned. The substrate which has a conductor layer on its surface has a thickness of usually 10 μm to 10 mm, preferably 20 μm to 5 mm, more preferably 30 μm to 2 mm.

The substrate which has a conductor layer on its surface used in the present invention is preferably pretreated on the surface of the conductor layer so as to improve the adhesion with the electrical insulating layer. As the method of pretreatment, known art can be used without particular limitation. For example, if the conductor layer is comprised of copper, the oxidizing method of bringing a strong alkaline oxidizing solution into contact with the conductor layer surface to form a layer of copper oxide on the conductor surface and roughen it, the method of oxidizing the conductor layer surface by the previous method, then reducing it by sodium borohydride, formalin, etc., the method of depositing plating on the conductor layer to roughen it, the method of bringing an organic acid into contact with the conductor layer to dissolve the grain boundaries of the copper and roughen the layer, the method of forming a primer layer on the conductor layer by a thiol compound, silane compound, etc. and the like may be mentioned. Among these, from the viewpoint of the ease of maintaining the shapes of fine wiring patterns, the method of bringing an organic acid into contact with the conductor layer to dissolve the grain boundaries of the copper and roughen the layer and the method of using thiol compounds or silane compounds etc. to form a primer layer are preferable.

The laminate of the present invention can usually be produced by hot pressing the above-mentioned film or prepreg of the present invention on a substrate which has a conductor layer on its surface.

As the method of hot pressing, the method of superposing a film with a support or prepreg on a substrate to contact the conductor layer and using a press laminator, press machine, vacuum laminator, vacuum press, roll laminator, or other pressure device for hot pressing (lamination) may be mentioned. By hot pressing, it is possible to join the conductor layer on the substrate surface and the film or prepreg with substantially no clearance at their interface. Note that, at this time, when the film of the present invention is a laminated film which has the adhesive layer which is comprised of the curable resin composition of the present invention and the plateable layer which is comprised of the plateable layer-use resin composition or when the prepreg of the present invention is comprised of such a laminated film and a fiber base material, the adhesive layer which forms the laminated film or prepreg is hot bonded in the state placed on the above substrate to contact the conductor layer. That is, hot bonding is performed in the state where the plateable layer is positioned at the surface (surface opposite to substrate).

The temperature of the hot bonding operation is usually 30 to 250° C., preferably 70 to 200° C., the pressure which is applied is usually 10 kPa to 20 MPa, preferably 100 kPa to 10 MPa, and the pressing time is usually 30 seconds to 5 hours, preferably 1 minute to 3 hours. Further, the hot bonding is preferably performed under reduced pressure to improve burying the wiring patterns into the insulating adhesive film or prepreg or to prevent the formation of bubbles. The pressure of the reduced pressure for performing the hot bonding is usually 100 kPa to 1 Pa, preferably 40 kPa to 10 Pa.

(Cured Article)

The cured article of the present invention can be obtained by treating the laminate of the present invention obtained by the above-mentioned method to cure the film or prepreg of the present invention. The curing is usually performed by heating the substrate as a whole on which the film or prepreg of the present invention is formed on the conductor layer. The curing can be performed simultaneously with the above-mentioned hot bonding operation. Further, the hot bonding operation may be performed under conditions where curing does not occur, that is, at a relative low temperature and short time, and then curing performed.

Further, for the purpose of improving the flatness of the electrical insulating layer or the purpose of increasing the thickness of the electrical insulating layer, it is also possible to bond two or more films or prepregs of the present invention on the conductor layer of the substrate for lamination.

The curing temperature is usually 30 to 400° C., preferably 70 to 300° C., more preferably 100 to 200° C. Further, the curing time is 0.1 to 5 hours, preferably 0.5 to 3 hours. The method of heating is not particularly limited. For example, an electrical oven etc. may be used for this.

(Composite Article)

The composite article of the present invention is comprised of an electrical insulating layer of a laminate of the present invention over which another conductor layer is further formed. As this conductor layer, a metal plating or metal foil may be used. In this case, when the film which forms the electrical insulating layer is a laminated film which has an adhesive layer which is comprised of the curable resin composition of the present invention and a plateable layer which is comprised of the plateable layer-use resin composition or when the prepreg which forms the electrical insulating layer is comprised of such a laminated film and a fiber base material, another conductor layer is formed on the plateable layer which is positioned on the surface (surface opposite to substrate).

As the metal plating material, gold, silver, copper, rhodium, palladium, nickel, tin, etc. may be mentioned. As the metal foil, one which is used as the support of the above-mentioned film or prepreg may be mentioned. Note that, in the present invention, the method of using a metal plating as a conductor layer is preferable from the viewpoint that fine micro wiring can be formed. Below, the method of production of the composite article of the present invention will be explained illustrating a multilayer circuit board which uses a metal plating as a conductor layer as one example of the composite article of the present invention.

First, the laminate is formed with via holes or through holes which pass through the electrical insulating layer. The via holes are formed for connecting the different conductor layers which form a multilayer circuit board when forming a multilayer circuit board. The via holes and through holes can be formed by chemical treatment such as photolithography or by physical treatment such as drilling, laser irradiation, and plasma etching. Among these methods, the method using a laser (CO₂ gas laser, excimer laser, UV-YAG laser, etc.) enables fine via holes to be formed without causing a drop in the characteristics of the electrical insulating layer, so this is preferred.

Next, the surface of the electrical insulating layer of the laminate (that is, the cured article of the present invention) is roughened by surface roughening treatment. The surface roughening treatment is performed so as to enhance the adhesion with the conductor layer which is formed on the electrical insulating layer.

The surface average roughness Ra of the electrical insulating layer is preferably 0.05 μm or more and less than 0.5 μm, more preferably 0.06 μm or more and less than 0.3 μm, while the surface 10-point average roughness Rzjis has a lower limit of preferably 0.3 μm or more, more preferably 0.5 μm or more, and has a lower limit of preferably less than 6 μm, more preferably 5 μm or less, furthermore preferably less than 4 μm, particularly preferably 2 μm or less. Note that, in this Description, Ra is the arithmetic average roughness which is shown in JIS B0601-2001, while the surface 10-point average roughness Rzjis is the 10-point average roughness which is shown in JIS B0601-2001 Annex 1.

The method of surface roughening treatment is not particularly limited, but the method of bringing the surface of the electrical insulating layer into contact with an oxidizing compound etc. may be mentioned. As the oxidizing compound, an inorganic oxidizing compound or organic oxidizing compound or other known compound which has an oxidizing ability may be mentioned. From the ease of control of the surface average roughness of the electrical insulating layer, use of an inorganic oxidizing compound or organic oxidizing compound is particularly preferable. As the inorganic oxidizing compound, a permanganate, chromic acid anhydride, dichromate, chromate, persulfate, active manganese dioxide, osmium tetraoxide, hydrogen peroxide, periodide, etc. may be mentioned. As the organic oxidizing compound, dicumyl peroxide, octanoyl peroxide, m-chloroperbenzoate, peracetate, ozone, etc. may be mentioned.

The method of using an inorganic oxidizing compound or organic oxidizing compound to roughen the surface of the electrical insulating layer is not particularly limited. For example, the method of dissolving the above oxidizing compound in a solvent which can dissolve it so as to prepare an oxidizing compound solution and bringing this into contact with the surface of the electrical insulating layer may be mentioned. The method of bringing the oxidizing compound solution into contact with the surface of the electrical insulating layer is not particularly limited, but, for example, the dipping method of dipping the electrical insulating layer in the oxidizing compound solution, the buildup method of utilizing the surface tension of the oxidizing compound solution to place the oxidizing compound solution on the electrical insulating layer, the spraying method of spraying the oxidizing compound solution on the electrical insulating layer, or any other method may also be used. By performing the surface roughening treatment, it is possible to improve the adhesion of the electrical insulating layer with the conductor layer and other layers.

The temperature and the time by which these oxidizing compound solutions are brought into contact with the surface of the electrical insulating layer may be freely set by considering the concentration and type of the oxidizing compound, method of contact, etc., but the temperature is usually 10 to 250° C., preferably 20 to 180° C., while the time is usually 0.5 to 60 minutes, preferably 1 to 40 minutes.

Note that, to remove the oxidizing compound after the surface roughening treatment, the surface of the electrical insulating layer after the surface roughening treatment is washed with water. Further, when a substance which cannot be washed off by just water is deposited on the surface, the surface is further washed by a washing solution which can dissolve that substance or another compound is brought into contact with the surface to convert the substance into one which can be dissolved in water and then the surface is washed by water. For example, when bringing an aqueous solution of potassium permanganate or an aqueous solution of sodium permanganate or other alkali aqueous solution into contact with the electrical insulating layer, to remove the film of manganese dioxide which is formed, it is possible to using a mixed solution of hydroxylamine sulfate and sulfuric acid or other acidic aqueous solution to neutralize/reduce the surface, then wash it by water.

Next, after the electrical insulating layer of the laminate is treated to roughen its surface, a conductor layer is formed on the surface of the electrical insulating layer and the inside wall surfaces of the via holes or through holes.

The method of formation of the conductor layer is performed, from the viewpoint of enabling formation of a conductor layer which is excellent in adhesion, using the electroless plating method.

For example, when using electroless plating to form a conductor layer, first, before forming a metal thin layer on the surface of the electrical insulating layer, the general practice has been to deposit silver, palladium, zinc, cobalt, or another catalyst nuclei on the electrical insulating layer. The method of depositing catalyst nuclei on the electrical insulating layer is not particularly limited, but, for example, the method of dipping the article in a solution obtained by dissolving silver, palladium, zinc, cobalt, or other metal compounds or their salts or complexes in water, alcohol, chloroform or another organic solvent in 0.001 to 10 wt % in concentration (in accordance with need, also possibly including an acid, alkali, complexing agent, reducing agent, etc.), then reducing the metal etc. may be mentioned.

As the electroless plating solution which is used in the electroless plating, a known self-catalyst type electroless plating solution may be used. It is not particularly limited in the type of metal, the type of reducing agent, the type of complexing agent, the concentration of hydrogen ions, the concentration of dissolved oxygen, etc. which are contained in the plating solution. For example, an electroless copper plating solution which contains ammonium hypophosphite, hypophosphoric acid, ammonium borohydride, hydrazine, formalin, etc. as a reducing agent; an electroless nickel-phosphorus plating solution which contains sodium hypophosphite as a reducing agent; an electroless nickel-boron plating solution which contains dimethylamineborane as a reducing agent; an electroless palladium plating solution; an electroless palladium-phosphorus plating solution which contains sodium hypophosphite as a reducing agent; an electroless gold plating solution; an electroless silver plating solution; an electroless nickel-cobalt-phosphorus plating solution which contains sodium hypophosphite as a reducing agent, or other electroless plating solution can be used.

After forming the metal thin layer, the substrate surface may be brought into contact with a rustproofing agent to make it rustproof. Further, after forming the metal thin layer, the metal thin layer may be heated to raise the adhesiveness. The heating temperature is usually 50 to 350° C., preferably 80 to 250° C. Note that, at this time, the heating may be performed under pressed conditions. As the pressing method at this time, for example, the method of using a hot press, a pressurizing and heating roll, and other physical pressing means may be mentioned. The pressure which is applied is usually 0.1 to 20 MPa, preferably 0.5 to 10 MPa. If this range, high adhesion can be secured between the metal thin layer and the electrical insulating layer.

The thus formed metal thin layer is formed with a plating-use resist pattern and the plating is further grown over it by electroplating or other wet plating (thickening plating). Next, the resist is removed and the surface is further etched to etch the metal thin layer into the pattern shapes and form the conductor layer. Therefore, the conductor layer which is formed by this method is usually comprised of the patterned metal thin layer and the plating which is grown over that.

Alternatively, when using metal foil instead of metal plating as the conductor layer which forms the multilayer circuit board, the following method can be used for production.

That is, first, the same procedure is followed as above to prepare a laminate which is comprised of an electrical insulating layer comprised of a film or prepreg and a conductor layer comprised of a metal foil. As such a laminate, when laminating and forming, it is preferable to make the curable resin composition a hardness enabling the required properties to be held and, due to this, it is preferable to prevent problems when subsequently working it or when forming a multilayer circuit board. In particular, it is preferable to form the laminate under a vacuum. Note that, a laminate which is comprised of such an electrical insulating layer comprised of a film or prepreg and a conductor layer comprised of a metal foil can, for example, be used for a printed circuit board by a known subtractive method.

Further, the prepared laminate is formed with, in the same way as above, via holes or through holes which pass through the electrical insulating layer, then the resin residue in the formed via holes is removed by desmearing the laminate which forms the through holes. The method of desmearing is not particularly limited, but for example the method of causing contact with a solution of permanganate or another oxidizing compound (desmearing solution) may be mentioned. Specifically, the laminate which is formed with the via holes can be dipped in a 60 to 80° C. aqueous solution which is adjusted to a concentration of sodium permanganate of 60 g/liter and a concentration of sodium hydroxide of 28 g/liters for 1 to 50 minutes with shaking so as to desmear it.

Next, after the laminate is desmeared, a conductor layer is formed at the inside wall surfaces of the via holes. The method of forming the conductor layer is not particularly limited, but it is possible to use either the electroless plating method or electroplating method. From the viewpoint of being able to form a conductor layer with a good adhesion, it is possible to use the electroless plating method in the same way as the method of forming a metal plating as the conductor layer.

Next, an electroless layer is formed on the inside wall surfaces of the via holes and on the copper foil, then the entire surface is electroplated, then the electroplated layer on the metal foil is formed with a resist pattern and, further, is etched to form patterns on the electroplated layer and metal foil and form a conductor layer. Alternatively, the inside wall surfaces of the via holes are formed with a conductor layer, then the metal foil is formed with a resist pattern for plating use and further electroplating or other wet plating is used to grow a plating (thick plating), then the resist is removed and the metal foil is further etched to pattern it by etching and form a conductor layer. Therefore, the conductor layer which is formed by this method is comprised of a patterned metal foil and plating which is grown on this.

By using the above obtained multilayer circuit board as the substrate for producing the above-mentioned laminate, hot pressing the above-mentioned shaped article or composite shaped article, and curing the same to form the electrical insulating layer and further forming a conductor layer on this in accordance with the above method, then repeating these steps, it is possible to form a further multilayer structure and thereby possible to obtain the desired multilayer circuit board.

The thus obtained composite article of the present invention (and multilayer circuit board constituting one example of the composite of the present invention) has an electrical insulating layer which is comprised of the curable resin composition of the present invention (cured article of the present invention). The electrical insulating layer is low in linear expansion and excellent in electrical characteristics, heat resistance, and wire embedding flatness, so the composite article of the present invention (and multilayer circuit board constituting one example of the composite of the present invention) can be suitably used for various applications.

Further, when making the electrical insulating layer of the composite article of the present invention a laminated film of an adhesive layer which is comprised of the curable resin composition of the present invention and a plateable layer which is comprised of the plateable layer-use resin composition or when making this a prepreg which is comprised of such a laminated film and fiber base material, the electrical insulating layer can be made one which is low in linear expansion and excellent in electrical characteristics, heat resistance, and wire burying flatness and further has a high peel strength. Further, in this case, it is possible to form a conductor layer at the electrical insulating layer and pattern the formed conductor layer and to pattern the conductor layer well when forming fine wirings.

(Substrate for Electronic Material Use)

The substrate for electronic material use of the present invention is comprised of the cured article or composite article of the present invention explained above. The substrate for electronic material use of the present invention which is comprised of the cured article or composite of the present invention can be suitably used for a mobile phone, PHS, laptop PCs, PDAs (personal digital assistants), mobile TV phones, PCs, super computers, servers, routers, liquid crystal projectors, engineering work stations (EWS), pagers, word processors, televisions, viewfinder type or monitor direct viewing type video tape recorders, electronic handheld devices, electronic desktop computers, car navigation systems, POS terminals, devices provided with touch panels, and other various electronic equipment.

### EXAMPLES

Below, examples and comparative examples will be given to explain the present invention more specifically. Note that, in the examples, the parts and percentages are based on weight unless otherwise indicated. The various physical properties were evaluated by the following methods.

(1) Number Average Molecular Weight (Mn) and Weight Average Molecular Weight (Mw) of Alicyclic Olefin Polymer

The number average molecular weight (Mn) and weight average molecular weight (Mw) of the alicyclic olefin polymer were measured by gel permeation chromatography (GPC) using tetrahydrofuran as a developing solvent and were found as values converted to polystyrene.

(2) Hydrogenation Ratio of Alicyclic Olefin Polymer

The ratio of the number of moles of the unsaturated bonds which were hydrogenated with respect to the number of moles of the unsaturated bonds in the polymer before the hydrogenation was found by measurement of the 400 MHz ¹H-NMR spectrum. This was used as the hydrogenation ratio.

(3) Content of Monomer Units Having Carboxylic Anhydride Groups in Alicyclic Olefin Polymer

The ratio of the number of moles of the monomer units which have carboxylic anhydride groups with respect to the number of moles of total monomer units in the polymer was found by measurement of the 400 MHz ¹H-NMR spectrum. This was used as the content of monomer units having carboxylic anhydride groups of the polymer.

(4) Wire Embedding Flatness

At the two sides of an inside layer circuit board (IPC MULTI-PURPOSE TESTBOARD No. IPC-B-25, conductor thickness 30 μm, 0.8 mm thickness), film shaped articles were laminated with the surfaces at the resin layer sides in contact. Specifically, the primary pressing operation was performed by hot pressing using a vacuum laminator which was provided with heat resistant rubber plates at the top and bottom under a reduced pressure of 200 Pa at a temperature of 110° C. and a pressure of 0.1 MPa for 90 seconds. Furthermore, a hydraulic press apparatus which was provided with metal press plates at the top and bottom was used to hot press the assembly at a press bonding temperature of 110° C. and 1 MPa for 90 seconds to obtain a laminate. Further, the support film was peeled off from this laminate and cured at 180° C. for 60 minutes. After curing, the step difference between the parts with conductors at comb-shaped pattern parts with a conductor width of 165 μm and conductor pitch of 165 μm and the parts without it were measured by a stylus type step difference thickness meter (P-10, made by Tencor Instruments Inc.). The wire embedding flatness was evaluated by the following criteria.

A: Step difference of less than 2 μm

B: Step difference of 2 μm or more and less than 3 μm

C: Step difference of 3 μm or more

(5) Specific Permittivity

A width 2.6 mm, length 80 mm, thickness 40 μm piece was cut out from a cured film shaped article, measured for specific permittivity at 10 GHz using a resonant cavity perturbation method permittivity measurement apparatus, and evaluated by the following criteria.

A: Specific permittivity of less than 3.15

B: Specific permittivity of 3.15 or more and less than 3.3

C: Specific permittivity of 3.3 or more

(6) Dielectric Tangent

A width 2.6 mm, length 80 mm, thickness 40 μm piece was cut out from a cured film shaped article, measured for dielectric tangent at 10 GHz using a resonant cavity perturbation method permittivity measurement apparatus, and evaluated by the following criteria.

A: Dielectric tangent of less than 0.008

B: Dielectric tangent of 0.008 or more and less than 0.012

C: Dielectric tangent of 0.012 or more

(7) Linear Expansion Coefficient

A width 6 mm, length 15.4 mm, thickness 40 μm piece was cut out from a cured film shaped article, measured for linear expansion coefficient at 30° C. to 150° C. under conditions of a distance between support points of 10 mm and a rate of temperature rise of 10° C./min using a thermomechanical analyzer (TMA/SDTA840: made by Mettler Toledo International Inc.), and evaluated by the following criteria.

A: Linear expansion coefficient of value of less than 30 ppm/° C.

B: Linear expansion coefficient of value of 30 ppm/° C. or more and less than 40 ppm/° C.

C: Linear expansion coefficient of value of 40 ppm/° C. or more

(8) Glass Transition Temperature (Tg)

The glass transition temperature (Tg) of the cured film shaped article was evaluated by drawing tangent lines to the curve around the glass transition temperature obtained under the above conditions by a thermomechnical analyzer (TMA), finding Tg from the point of intersection with these tangent lines, and evaluating it by the following criteria.

A: Glass transition temperature of 160° C. or more

B: Glass transition temperature of 150° C. or more and less than 160° C.

C: Glass transition temperature of less than 150° C.

(9) Peel Strength

The peel strength between the insulating layer and copper plated layer in the multilayer printed circuit board was measured based on JIS C6481-1996 and evaluated by the following criteria. Note that, the peel strength was evaluated for only Examples 2-1 to 2-6 and Comparative Examples 2-1 to 2-3 in the examples and comparative examples.

A: Peel strength of 5N/cm or more

C: Peel strength of less than 5N/cm

### Synthesis Example 1

70 molar parts of tetracyclo[9.2.1.0^{2,10}.0^{3,8}]tetradeca-3,5,7,12-tetraene (methanotetrahydrofluorene) (IMF), 30 molar parts of bicyclo[2.2.1]hept-2-ene-5,6-dicarboxylic anhydride (NDCA), 6 molar parts of 1-hexene, 590 molar parts of anisole, and 0.015 molar part of a ruthenium-based polymerization catalyst constituted by 4-acetoxybenzylidene(dichloro)(4,5-dibromo-1,3-dimesityl-4-imidazolin-2-ylidene)(tricyclohexylphosphine)ruthenium (C1063, made by Wako Pure Chemicals Industries, Ltd.) were charged into a nitrogen-substituted pressure resistant glass reactor and were reacted while stirring at 80° C. for 1 hour for polymerization to obtain a solution of a ring-opening polymer. This solution was measured by gas chromatography, whereby it was confirmed that substantially no monomer remained and the polymer conversion rate was 99% or more.

Next, a nitrogen-substituted autoclave equipped with a stirrer was charged with the obtained solution of the ring-opening polymer. This was stirred at 150° C., by a hydrogen pressure of 7 MPa, for 5 hours to perform a hydrogenation reaction. Next, the obtained hydrogenation reaction solution was concentrated to obtain a solution of the alicyclic olefin polymer (A4-1). The obtained alicyclic olefin polymer (A4-1) had a weight average molecular weight of 10,000, a number average molecular weight of 5,000, and a molecular weight distribution of 2. Further, the hydrogenation rate was 97%, while the content of the monomer units which have carboxylic anhydride groups was 30 mol %. The solid concentration of the solution of the alicyclic olefin polymer (A4-1) was 55%. Further, the epoxy reactive group equivalents of the alicyclic olefin polymer (A4-1) was 589.

### Synthesis Example 2

Except for changing the amount of the tetracyclo[9.2.1.0^{2,10}.0^{3,8}]tetradeca-3,5,7,12-tetraene (MTF) from 70 molar parts to 90 molar parts and the amount of the bicyclo[2.2.1]hept-2-ene-5,6-dicarboxylic anhydride (NDCA) from 30 molar parts to 10 molar parts respectively, the same procedure was followed as in Synthesis Example 1 to obtain a solution of the alicyclic olefin polymer (A4-2). The obtained alicyclic olefin polymer (A4-2) had a weight average molecular weight of 10,000, a number average molecular weight of 5,000, and a molecular weight distribution of 2. Further, the hydrogenation rate was 96%, and the content of the monomer units which have carboxylic anhydride groups was 10 mol %. The solid concentration of the solution of the alicyclic olefin polymer (A4-2) was 55%. Further, the epoxy reactive group equivalents of the alicyclic olefin polymer (A4-2) was 1805.

### Synthesis Example 3

As the first stage of polymerization, 35 molar parts of 5-ethylidene-bicyclo[2.2.1]hept-2-ene (EdNB), 0.9 molar part of 1-hexene, 340 molar parts of anisole, and 0.005 molar part of C1063 were charged into a nitrogen-substituted pressure resistant glass reactor. The mixture was reacted while stirring at 80° C. for 30 minutes for polymerization to obtain a solution of a norbornene-based ring-opening polymer.

Next, as the second stage of polymerization, to the solution which was obtained in the first stage of polymerization, 35 molar parts of tetracyclo[9.2.1.0^{2,10}.0^{3,8}]tetradeca-3,5,7,12-tetraene (MTF), 30 molar parts of bicyclo[2.2.1]hept-2-ene-5,6-dicarboxylic anhydride (NDCA), 250 molar parts of anisole, and 0.01 molar part of C1063 were added. The mixture was reacted while stirring at 80° C. for 1.5 hours for polymerization to obtain a solution of a norbornene-based ring-opening polymer. This solution was measured by gas chromatography whereupon it was confirmed that substantially no monomers remained and whereupon the polymerization conversion rate was 99% or more.

Next, a nitrogen-substituted autoclave equipped with a stirrer was charged with the obtained solution of a ring-opening polymer, 0.03 molar part of C1063 was further added, and the mixture was reacted at 150° C. at a hydrogen pressure of 7 MPa for 5 hours for hydrogenation to obtain a solution of a hydrogenated product of a norbornene-based ring-opening polymer constituted by the alicyclic olefin polymer (B1-1). The obtained polymer (B1-1) had a weight average molecular weight of 60,000, a number average molecular weight of 30,000, and a molecular weight distribution of 2. Further, the hydrogenation rate was 95%, and the content of the repeating units which have carboxylic anhydride groups was 30 mol %. The solid concentration of the solution of the polymer (B1-1) was 22%.

### Synthesis Example 4

70 molar parts of tetracyclo[9.2.1.0^{2,10}.0^{3,8}]tetradeca-3,5,7,12-tetraene (MTF), 30 molar parts of bicyclo[2.2.1]hept-2-ene-5,6-dicarboxylic anhydride (NDCA), 0.9 molar part of 1-hexene, 590 molar parts of anisole, and 0.015 molar part of C1063 were charged into a nitrogen-substituted pressure resistant glass reactor. The mixture was reacted while stirring at 80° C. for 1 hour for polymerization to obtain a solution of a norbornene-based ring-opening polymer. This solution was measured by gas chromatography whereupon it was confirmed that substantially no monomers remained and the polymerization conversion rate was 99% or more.

Next, a nitrogen-substituted autoclave equipped with a stirrer was charged with the obtained solution of a ring-opening polymer and reacted at 150° C. at a hydrogen pressure of 7 MPa for 5 hours for hydrogenation to obtain a solution of a hydrogenated product of a norbornene-based ring-opening polymer constituted by the alicyclic olefin polymer (B1-2). The obtained polymer (B1-2) had a weight average molecular weight of 50,000, a number average molecular weight of 26,000, and a molecular weight distribution of 1.9. Further, the hydrogenation rate was 97%, and the content of the repeating units which have carboxylic anhydride groups was 30 mol %. The solid concentration of the solution of the polymer (B1-2) was 22%.

### Example 1-1

### Preparation of Curable Resin Composition

100 parts of an epoxy compound (A1) constituted by a dicyclopentadiene-type epoxy resin (product name “EPICLON HP-7200HH”, made by DIC Corporation, epoxy group equivalents 280), 112 parts of an active ester compound (A2) constituted by an active ester resin (product name “EPICLON HPC-8000-65T”, 65 wt % nonvolatile content of toluene solution, made by DIC Corporation, active ester group equivalents 223) (as amount of active ester resin, 73 parts), 18 parts of a solution of the alicyclic olefin polymer (A4-1) which was obtained in Synthesis Example 1 (epoxy reactive group equivalents 589) (as amount of alicyclic olefin polymer, 10 parts), 356 parts of a filler (A3) constituted by silica (product name “SC2500-SXJ”, made by Admatechs Company Limited), 1 part of an antiaging agent constituted by a hindered phenol-based antioxidant (product name “IRGANOX 3114”, made by BASF), and 110 parts of anisole were mixed and stirred by a planetary mixer for 3 minutes.

Furthermore, to this, 13 parts (4 parts of curing accelerator therein) of a solution of a curing accelerator constituted by 1-benzyl-2-phenylimidazole dissolved in anisole to 30% in was mixed and stirred by a planetary mixer for 5 minutes to obtain a varnish of the curable resin composition (A-1).

(Preparation of Film Shaped Article)

Next, the above obtained varnish of the curable resin composition was applied by a die coater on a vertical 300 mm×horizontal 300 mm size, thickness 38 μm, surface average roughness Ra 0.08 μm polyethylene terephthalate film (support: Lumirror (registered trademark) T60, made by Toray Industries Inc.), then dried in a nitrogen atmosphere at 80° C. for 10 minutes to obtain a film shaped article of thickness 43 μm resin composition on a support. Further, the obtained film shaped article was used in accordance with the above method to measure the wire embedding flatness. The results are shown in Table 1.

(Preparation of Film-Shaped Cured Article)

Next, a piece which was cut out from the thus obtained film shaped article of the curable resin composition was placed on a thickness 10 μm copper foil. This was set, in the state with the support attached, so that the adhesive layer became the inside. A vacuum laminator which was provided with heat resistant rubber press plates at the top and bottom was used to reduce the pressure to 200 Pa and hot press bond the laminate at a temperature of 110° C. and a pressure of 0.1 MPa for 60 seconds, the support was peeled off, then the laminate was heated and cured at 180° C. for 120 minutes in the air. After curing, the cured resin with the copper foil was cut out and the copper foil was dissolved in a 1 mol/liter ammonium persulfate aqueous solution to obtain a film-shaped cured article. The obtained film-shaped cured article was used in accordance with the above methods to measure the specific permittivity, dielectric tangent, linear expansion coefficient, and glass transition temperature. The results are shown in Table 1.

### Example 1-2

Except for changing the amount of the active ester compound (A2) constituted by EPICLON HPC-8000-65T from 112 parts to 108 parts (as amount of active ester resin, 73 parts to 70 parts), the amount of the solution of the alicyclic olefin polymer (A4-1) from 18 parts to 36 parts (as amount of alicyclic olefin polymer (A4-1), from 10 parts to 20 parts), and the amount of silica from 356 parts to 358 parts, the same procedure was followed as in Example 1-1 to obtain a varnish of the curable resin composition (A-2), film shaped article, and film-shaped cured article and the same procedure was followed to evaluate them. The results are shown in Table 1.

### Example 1-3

Except for using, instead of the alicyclic olefin polymer (A1-1), the alicyclic olefin polymer (A1-2) which was obtained in Synthetic Example 2, the same procedure was followed as in Example 1-1 to obtain a varnish of the curable resin composition (A-3), film shaped article, and film-shaped cured article and the same procedure was followed to evaluate them. The results are shown in Table 1.

### Example 1-4

Except for changing the amount of the active ester compound (A2) constituted by EPICLON HPC-8000-65T from 112 parts to 77 parts (as amount of active ester resin, from 73 parts to 50 parts), the amount of the solution of the alicyclic olefin polymer (A4-1) from 18 parts to 27 parts (as amount of alicyclic olefin polymer (A4-1), 10 parts to 15 parts), and the amount of silica from 356 parts to 315 parts, the same procedure was followed as in Example 1-1 to obtain a varnish of the curable resin composition (A-4), film shaped article, and film-shaped cured article and the same procedure was followed to evaluate them. The results are shown in Table 1.

### Example 1-5

Except for changing the amount of the active ester compound (A2) constituted by EPICLON HPC-8000-65T from 112 parts to 231 parts (as amount of active ester resin, from 73 parts to 150 parts), the amount of the solution of the alicyclic olefin polymer (A4-1) from 18 parts to 36 parts (as amount of alicyclic olefin polymer (A4-1), 10 parts to 20 parts), and the amount of silica from 356 parts to 500 parts, the same procedure was followed as in Example 1-1 to obtain a varnish of the curable resin composition (A-5), film shaped article, and film-shaped cured article and the same procedure was followed to evaluate them. The results are shown in Table 1.

### Example 1-6

Except for placing glass cloth (1037 Type, thickness 25 μm, made by Nitto Boseki Company Limited) on a thickness 38 μm polyethylene terephthalate film (support: Lumirror (registered trademark) T60, made by Toray Industries Inc.), then applying the curable resin composition (A-1) which was obtained in Example 1-1 using a die coater, the same procedure was followed as in Example 1-1 to impregnate the curable resin composition (A-1) in the glass cloth to obtain a prepreg and film-shaped cured article and the same procedure was followed to evaluate them. The results are shown in Table 1.

### Comparative Example 1-1

Except for changing the amount of the active ester compound (A2) constituted by EPICLON HPC-8000-65T from 112 parts to 108 parts (as amount of active ester resin, from 73 parts to 70 parts), the amount of the solution of the alicyclic olefin polymer (A4-2) from 18 parts to 118 parts (as amount of alicyclic olefin polymer (A4-2), 10 parts to 65 parts), and the amount of silica from 356 parts to 450 parts, the same procedure was followed as in Example 1-3 to obtain a varnish of the curable resin composition (A-6), film shaped article, and film-shaped cured article and the same procedure was followed to evaluate them. The results are shown in Table 1.

### Comparative Example 1-2

Except for changing the amount of the solution of the alicyclic olefin polymer (A4-2) from 18 parts to 3 parts (as amount of alicyclic olefin polymer (A4-2), from 10 parts to 1.5 parts), and the amount of silica from 356 parts to 330 parts, the same procedure was followed as in Example 1-3 to obtain a varnish of the curable resin composition (A-7), film shaped article, and film-shaped cured article and the same procedure was followed to evaluate them. The results are shown in Table 1.

### Comparative Example 1-3

Except for not mixing in the alicyclic olefin polymer (A4-1) and changing the amount of silica from 356 parts to 330 parts, the same procedure was followed as in Example 1-1 to obtain a varnish of the curable resin composition (A-8), film shaped article, and film-shaped cured article and the same procedure was followed to evaluate them. The results are shown in Table 1.

TABLE 1

| Examples | | | | | | Comparative Examples | | |
|---|---|---|---|---|---|---|---|---|
| 1-1 | 1-2 | 1-3 | 1-4 | 1-5 | 1-6 | 1-1 | 1-2 | 1-3 |

Composition of curable resin composition

| | | | | | | | | | | |
|---|---|---|---|---|---|---|---|---|---|---|
| Epoxy compound (A1) (epoxy group | (parts) | 100 | 100 | 100 | 100 | 100 | 100 | 100 | 100 | 100 |
| equivalents 280) | | | | | | | | | | |
| Active ester compounds (A2) (active ester equivalents | (parts) | 73 | 70 | 73 | 50 | 150 | 73 | 70 | 73 | 73 |
| 223) | | | | | | | | | | |
| Filler (A3) | (parts) | 356 | 358 | 356 | 315 | 500 | 356 | 450 | 330 | 330 |
| Alicyclic olefin polymer (A4-1) (epoxy reactive group | (parts) | 10 | 20 | — | 15 | 20 | 10 | — | — | — |
| equivalents 589) | | | | | | | | | | |
| Alicyclic olefin polymer (A4-2) (epoxy reactive group | (parts) | — | — | 10 | — | — | — | 65 | 1.5 | — |
| equivalents 1805) | | | | | | | | | | |
| Antiaging agent | (parts) | 1 | 1 | 1 | 1 | 1 | 1 | 1 | 1 | 1 |
| Curing accelerator | (parts) | 4 | 4 | 4 | 4 | 4 | 4 | 4 | 4 | 4 |
| Ratio of content of filler (A3) in curable resin | (%) | 65 | 65 | 65 | 65 | 65 | 65 | 65 | 65 | 65 |
| composition | | | | | | | | | | |
| Equivalent ratio of epoxy groups/(active ester | | 1.04 | 1.03 | 1.07 | 1.43 | 0.51 | 1.04 | 1.02 | 1.09 | 1.09 |
| groups + epoxy reactive groups) | | | | | | | | | | |
| Fiber base material | | None | None | None | None | None | Yes | None | None | None |

Results of evaluation

| | | | | | | | | | |
|---|---|---|---|---|---|---|---|---|---|
| Wire embedding flatness | A | A | A | A | A | B | C | A | A |
| Specific permittivity | A | A | A | B | A | A | A | A | A |
| Dielectric tangent | A | A | A | B | A | A | A | A | A |
| Linear expansion coefficient | A | A | A | B | B | A | C | C | B |
| Glass transition temperature (Tg) | A | A | A | B | B | A | C | C | C |

(Evaluation of Examples 1-1 to 1-6 and Comparative Examples 1-1 to 1-3)

As shown in Table 1, it can be confirmed that by using the curable resin composition of the present invention, it is possible to make the obtained electrical insulating layer (resin layer) one which is low in linear expansion and excellent in wire embedding flatness, electrical characteristics (specific permittivity and dielectric tangent), and heat resistance (Examples 1-1 to 1-6).

On the other hand, if the amount of the alicyclic olefin polymer (A4) was too great, the obtained electrical insulating layer (resin layer) became high in linear expansion coefficient and inferior in wire embedding flatness and heat resistance (Comparative Example 1-1).

Further, if the amount of the alicyclic olefin polymer (A4) was too small, the obtained electrical insulating layer (resin layer) became high in linear expansion coefficient and inferior in heat resistance (Comparative Example 1-2).

Furthermore, if not mixing in the alicyclic olefin polymer (A4), the obtained electrical insulating layer (resin layer) became inferior in heat resistance (Comparative Example 1-3).

### Example 2-1

### Curable Resin Composition

The same procedure was followed as in Example 1-1 to obtain a varnish of the curable resin composition (A-1).

(Plateable Layer-Use Resin Composition)

450 parts of the solution of the alicyclic olefin polymer (B1-1) which was obtained in Synthesis Example 3, and 113 parts of silica slurry which was obtained by mixing 40% of spherical silica (Admafine S0-C1, made by Admatechs Company Limited, volume average particle diameter 0.25 μm) and 2% of the alicyclic olefin polymer (B1-2) which was obtained in Synthesis Example 4 in anisole were mixed and stirred by a planetary type mixer for 3 minutes.

To this, 35.8 parts of a curing agent (B2) constituted by a solution of 70% of multifunctional epoxy resin (1032H60, made by Mitsubishi Chemical Corporation, epoxy equivalents 163 to 175) dissolved in anisole, 1 part of a laser processability enhancing agent constituted by 2-[2-hydroxy-3,5-bis(α,α-dimethylbenzyl)phenyl]-2H-benzotriazole, 1 part of a hindered phenol compound constituted by tris-(3,5-di-t-butyl-4-hydroxybenzyl)-isocyanulate (IRGANOX (registered trademark) 3114, made by BASF), 1 part of a hindered amine compound constituted by tetrakis(1,2,2,6,6-pentamethyl-4-piperidyl)1,2,3,4-butanetetracarboxylate (Adekastab (registered trademark) LA52, made by ADEKA CORPORATION), 3 parts of an elastomer constituted by a solution of 80% of liquid epoxylated polybutadiene (Ricon 657, made by Sartomer Japan Inc.) dissolved in anisole, and 553 parts of anisole were mixed and stirred by a planetary mixer for 3 minutes.

Furthermore, to this, 10 parts of a solution in which a curing accelerator constituted by 5% of 1-benzyl-2-phenylimidazole was dissolved in anisole was mixed. The mixture was stirred by a planetary mixer for 5 minutes to obtain a varnish of a plateable layer-use resin composition (B-1). The varnish had a viscosity of 70 mPa·sec.

(Preparation of Film Composite)

The varnish of the plateable layer-use resin composition (B-1) which was obtained above was applied on a thickness 100 μm polyethylene terephthalate film (support) by using a wire bar, then was dried in a nitrogen atmosphere at 130° C. for 10 minutes to obtain a film with a support on which a thickness 3 μm plateable layer comprised of an uncured plateable layer-use resin composition (B-1) was formed.

Next, the surface of the film with the support on which the plateable layer comprised of the plateable layer-use resin composition (B-1) was formed was coated with the varnish of the curable resin composition (A-1) which was obtained above by using a doctor blade (made by Tester Sangyo Co., Ltd) and an auto film applicator (made by Tester Sangyo Co., Ltd), then was dried in a nitrogen atmosphere at 80° C. for 10 minutes to obtain a film composite with the support on which a total thickness 43 μm plateable layer and adhesive layer were formed. The film composite with the support was formed by the support, the plateable layer comprised of the plateable layer-use resin composition (B-1), and the adhesive layer comprised of the adhesive layer-use resin composition (A-1) in that order. Further, the obtained film composite with the support was measured for wire embedding flatness in accordance with the above method. The results are shown in Table 2.

(Preparation of Film-Shaped Cured Article)

Next, thickness 10 dun copper foil was placed on a copper-clad multilayer substrate. From above, the thus obtained film composite with the support was set, in the state with the support attached, so that the adhesive layer became the inside. A vacuum laminator which was provided with heat resistant rubber press plates at the top and bottom was used to reduce the pressure to 200 Pa and perform a hot press bonding to obtain a laminate at a temperature of 110° C. and a pressure of 0.1 MPa for 60 seconds, the support was peeled off, then heat and cure the laminate at 180° C. for 120 minutes in the air. After curing, the cured resin with the copper foil was cut out. The copper foil was dissolved in a 1 mol/liter ammonium persulfate aqueous solution to obtain a film-shaped cured article. Further, the obtained film-shaped cured article was measured for specific permittivity, dielectric tangent, linear expansion coefficient, and glass transition temperature in accordance with the above methods. The results are shown in Table 2.

(Preparation of Laminate)

Next, separate from the above, a varnish which contained a glass filler and halogen-free epoxy resin was made to impregnate the glass fibers to obtain a core material. On the surface of this, thickness 18 μm copper was laid to obtain a thickness 0.8 mm×150 mm square (vertical 150 mm×horizontal 150 mm) two-sided copper-clad multilayer substrate. The surface of this was formed with a conductor layer which was microetched by contact of the surface with an organic acid to give a line width and line pitch of 50 μm and a thickness of 30 μm and thereby obtain an inside layer substrate.

At the two sides of this inside layer substrate, pieces of the above obtained film composite with the support which were cut into 150 mm squares were superposed so that the plateable layer-use resin composition (B-1) sides were at the insides, then the assembly was pressed by a primary pressing operation. The primary pressing operation was hot pressing by a vacuum laminator which was provided with heat resistant rubber press plates at the top and bottom under a reduced pressure of 200 Pa at a temperature of 110° C. and a pressure of 0.1 MPa for 90 seconds. Furthermore, a hydraulic press apparatus which was provided with metal press plates at the top and bottom was used to hot press the assembly at a press bonding temperature of 110° C. and 1 MPa for 90 seconds. Next, the support was peeled off to thereby obtain a laminate of a resin layer which was comprised of the curable resin composition (A-1) and the plateable layer-use resin composition (B-1) and the inside layer substrate. Furthermore, the laminate was allowed to stand in an air atmosphere at 180° C. for 60 minutes to make the resin layer cure and form an electrical insulating layer on the inside layer substrate.

(Swelling Treatment Step)

The obtained laminate was dipped while shaking in a 60° C. aqueous solution which was prepared to contain a swelling solution (“Swelling Dip Securiganth P”, made by Atotech, “Securiganth” is a registered trademark) 500 ml/liter and sodium hydroxide 3 g/liter for 15 minutes, then was rinsed.

(Oxidizing Treatment Step)

Next, the laminate was dipped while shaking in an 70° C. aqueous solution which was prepared to contain an aqueous solution of permanganate (“Concentrate Compact CP”, made by Atotech) 500 ml/liter and a concentration of sodium hydroxide of 40 g/liter for 15 minutes, then was rinsed.

(Neutralizing/Reduction Treatment Step)

Next, the laminate was dipped in a 40° C. aqueous solution which was prepared to contain an aqueous solution of hydroxylamine sulfate (“Reduction Securiganth P 500”, made by Atotech, “Securiganth” is a registered trademark) 100 ml/liter and sulfuric acid 35 ml/liter for 5 minutes to neutralize and reduce it, then was rinsed.

(Cleaner/Conditioner Step)

Next, the laminate was dipped in a 50° C. aqueous solution which was prepared to contain a cleaner/conditioner aqueous solution (“Alcup MCC-6-A”, made by Uyemura & Co., Ltd. “Alcup” is a registered trademark) of a concentration of 50 ml/liter for 5 minutes to treat it with the cleaner and conditioner. Next, the laminate was dipped in 40° C. rinsing water for 1 minute, then was rinsed.

(Soft Etching Step)

Next, the laminate was dipped in an aqueous solution which was prepared to contain a sulfuric acid concentration of 100 g/liter and sodium persulfate of 100 g/liter for 2 minutes to be soft etched, then was rinsed.

(Pickling Step)

Next, the laminate was dipped in an aqueous solution which was prepared to contain a sulfuric acid concentration of 100 g/liter for 1 minute to be pickled, then was rinsed.

(Catalyst Imparting Step)

Next, the laminate was dipped in a 60° C. Pd salt-containing plating catalyst aqueous solution which was prepared to contain Alcup Activator MAT-1-A (product name, made by Uyemura & Co., Ltd. “Alcup” is a registered trademark) 200 ml/liter, Alcup Activator MAT-1-B (product name, made by Uyemura & Co., Ltd. “Alcup” is a registered trademark) 30 ml/liter, and sodium hydroxide 0.35 g/liter for 5 minutes, then was rinsed.

(Activation Step)

Next, the laminate was dipped in an aqueous solution which was prepared to contain Alcup Reducer MAB-4-A (product name, made by Uyemura & Co., “Alcup” is a registered trademark) 20 ml/liter and Alcup Reducer MAB-4-B (product name, made by Uyemura & Co., Ltd. “Alcup” is a registered trademark) 200 ml/liter at 35° C. for 3 minutes to reduce the plating catalyst, then was rinsed.

(Accelerator Treatment Step)

Next, the laminate was dipped in an aqueous solution which was prepared to contain Alcup Accelerator MEL-3-A (product name, made by Uyemura & Co., Ltd. “Alcup” is a registered trademark) 50 ml/liter at 25° C. for 1 minute.

(Electroless Plating Step)

The thus obtained laminate was dipped in an electroless copper plating solution which was prepared to contain Thru-Cup PEA-6-A (product name, made by Uyemura & Co., Ltd. “Thru-Cup” is a registered trademark) 100 ml/liter, Thru-Cup PEA-6-B-2X (product name, made by Uyemura & Co. Ltd.) 50 ml/liter, Thru-Cup PEA-6-C (product name, made by Uyemura & Co. Ltd.) 14 ml/liter, Thru-Cup PEA-6-D (product name, made by Uyemura & Co. Ltd.) 15 ml/liter, Thru-Cup PEA-6-E (product name, made by Uyemura & Co. Ltd.) 50 ml/liter, and 37 wt % formalin aqueous solution 5 ml/liter, while blowing in air, at a temperature of 36° C. for 20 minutes for electroless copper plating so as to form an electroless plating film on the laminate surface (surface of plateable layer comprised of plateable layer-use resin composition (B-1)).

Next, the laminate which was formed with the electroless plating film was dipped in a corrosion inhibiting solution which was prepared to contain AT-21 (product name, made by Uyemura & Co. Ltd.) in 10 ml/liter at room temperature for 1 minute, then was rinsed. Furthermore, this was dried to prepare a corrosion-resistant treated laminate. This corrosion-resistant treated laminate was annealed in an air atmosphere at 150° C. for 30 minutes.

The annealed laminate was electroplated with copper to form a thickness 18 μm electroplated copper layer. Next, the laminate was heat treated at 180° C. for 60 minutes to thereby obtain a two-sided two-layer multilayer printed circuit board comprised of a laminate on which circuits are formed by conductor layers which are comprised of the metal thin film layers and electroplated copper layers. Further, the obtained multilayer printed circuit board was measured for peel strength in accordance with the above method. The results are shown in Table 2.

### Example 2-2

Except for using, instead of the varnish of the curable resin composition (A-1), a varnish of the curable resin composition (A-2) which was obtained in the same way as in Example 1-2, the same procedure was followed as in Example 2-1 to obtain a film composite with a support, film-shaped cured article, and multilayer printed circuit board and the same procedure was followed to evaluate them. The results are shown in Table 2.

### Example 2-3

Except for using, instead of the varnish of the curable resin composition (A-1), a varnish of the curable resin composition (A-3) which was obtained in the same way as in Example 1-3, the same procedure was followed as in Example 2-1 to obtain a film composite with a support, film-shaped cured article, and multilayer printed circuit board and the same procedure was followed to evaluate them. The results are shown in Table 2.

### Example 2-4

Except for using, instead of the varnish of the curable resin composition (A-1), a varnish of the curable resin composition (A-4) which was obtained in the same way as in Example 1-4, the same procedure was followed as in Example 2-1 to obtain a film composite with a support, film-shaped cured article, and multilayer printed circuit board and the same procedure was followed to evaluate them. The results are shown in Table 2.

### Example 2-5

Except for using, instead of the varnish of the curable resin composition (A-1), a varnish of the curable resin composition (A-5) which was obtained in the same way as in Example 1-5, the same procedure was followed as in Example 2-1 to obtain a film composite with a support, film-shaped cured article, and multilayer printed circuit board and the same procedure was followed to evaluate them. The results are shown in Table 2.

### Example 2-6

The surface of the film composite with the support which was obtained in Example 2-1 on which the plateable layer-use resin composition which was comprised of the plateable layer-use resin composition (B-1) was formed was coated with the curable resin composition (A-1) which was obtained in Example 2-1, then was dried in a nitrogen atmosphere at 80° C. for 3 minutes to obtain a film composite with the support which was formed with a plateable layer and adhesive layer with a total thickness of the plateable layer and adhesive layer of 6 μm. Furthermore, glass cloth (1027 Type, thickness 20 μm, made by Nitto Boseki Company Limited) was placed on the surface of the composite on which the adhesive layer was formed, the curable resin composition (A-1) which was obtained in Example 2-1 was applied from above to impregnate the glass cloth, then this was dried in a nitrogen atmosphere at 80° C. for 10 minutes to obtain a prepreg with the support which was formed with a support with a total thickness of 43 μm, a plateable layer which is comprised of the plateable layer-use resin composition (B-1), a layer which is comprised of a curable resin composition (A-1), a glass cloth layer, and an adhesive layer which is comprised of a layer which is comprised of a curable resin composition (A-1) in that order. Further, the obtained prepreg was used in the same way as Example 2-1 to obtain a film-shaped cured article and multilayer printed circuit board and the same procedure was followed to evaluate them. The results are shown in Table 2.

### Comparative Example 2-1

Except for using, instead of the varnish of the curable resin composition (A-1), a varnish of the curable resin composition (A-6) which was obtained in the same way as in Comparative Example 1-1, the same procedure was followed as in Example 2-1 to obtain a film composite with a support, film-shaped cured article, and multilayer printed circuit board and the same procedure was followed to evaluate them. The results are shown in Table 2.

### Comparative Example 2-2

Except for using, instead of the varnish of the curable resin composition (A-1), a varnish of the curable resin composition (A-7) which was obtained in the same way as in Comparative Example 1-2, the same procedure was followed as in Example 2-1 to obtain a film composite with a support, film-shaped cured article, and multilayer printed circuit board and the same procedure was followed to evaluate them. The results are shown in Table 2.

### Comparative Example 2-3

Except for using, instead of the varnish of the curable resin composition (A-1), a varnish of the curable resin composition (A-8) which was obtained in the same way as in Comparative Example 1-3, the same procedure was followed as in Example 2-1 to obtain a film composite with a support, film-shaped cured article, and multilayer printed circuit board and the same procedure was followed to evaluate them. The results are shown in Table 2.

TABLE 2

| Examples | | | | | | Comparative Examples | | |
|---|---|---|---|---|---|---|---|---|
| 2-1 | 2-2 | 2-3 | 2-4 | 2-5 | 2-6 | 2-1 | 2-2 | 2-3 |

Composition of curable resin composition

| | | | | | | | | | | |
|---|---|---|---|---|---|---|---|---|---|---|
| Epoxy compound (A1) (epoxy group equivalents 280) | (parts) | 100 | 100 | 100 | 100 | 100 | 100 | 100 | 100 | 100 |
| Active ester compounds (A2) (active ester equivalents | (parts) | 73 | 70 | 73 | 50 | 150 | 73 | 70 | 73 | 73 |
| 223) | | | | | | | | | | |
| Filler (A3) | (parts) | 356 | 358 | 356 | 315 | 500 | 356 | 450 | 330 | 330 |
| Alicyclic olefin polymer (A4-1) (epoxy reactive group | (parts) | 10 | 20 | — | 15 | 20 | 10 | — | — | — |
| equivalents 589) | | | | | | | | | | |
| Alicyclic olefin polymer (A4-2) (epoxy reactive group | (parts) | — | — | 10 | 13 | — | — | 65 | 1.5 | — |
| equivalents 1805) | | | | | | | | | | |
| Antiaging agent | (parts) | 1 | 1 | 1 | 1 | 1 | 1 | 1 | 1 | 1 |
| Curing accelerator | (parts) | 4 | 4 | 4 | 4 | 4 | 4 | 4 | 4 | 4 |
| Ratio of content of filler (A3) in curable resin | (%) | 65 | 65 | 65 | 65 | 65 | 65 | 65 | 65 | 65 |
| composition | | | | | | | | | | |
| Equivalent ratio of epoxy groups/(active ester groups + | | 1.04 | 1.03 | 1.07 | 1.43 | 0.51 | 1.04 | 1.02 | 1.09 | 1.09 |
| epoxy reactive groups) | | | | | | | | | | |
| Fiber base material | | None | None | None | None | None | Yes | None | None | None |

Results of evaluation

| | | | | | | | | | |
|---|---|---|---|---|---|---|---|---|---|
| Wire embedding flatness | A | A | A | A | A | B | C | A | A |
| Specific permittivity | A | A | A | B | A | A | A | A | A |
| Dielectric tangent | A | A | A | B | A | A | A | A | A |
| Linear expansion coefficient | A | A | A | B | B | A | C | C | B |
| Glass transition temperature (Tg) | A | A | A | B | B | A | C | C | C |
| Peel strength | A | A | A | A | A | A | A | A | A |

Evaluation of Examples 2-1 to 2-6 and Comparative Examples 2-1 to 2-3

As shown in Table 2, it can be confirmed that by using as the resin composition which forms the adhesive layer the curable resin composition of the present invention, the obtained electrical insulating layer (resin layer) can be made low in linear expansion and excellent in wire embedding flatness, electrical characteristics (specific permittivity and dielectric tangent), heat resistance, and peel strength (Examples 2-1 to 2-6).

On the other hand, if the amount of the alicyclic olefin polymer (A4) in the curable resin composition was too great, the obtained electrical insulating layer (resin layer) became high in linear expansion coefficient and inferior in wire embedding flatness and heat resistance (Comparative Example 2-1).

Further, if the amount of the alicyclic olefin polymer (A4) in the curable resin composition was too small, the obtained electrical insulating layer (resin layer) became high in linear expansion coefficient and inferior in heat resistance (Comparative Example 2-2).

Furthermore, if not mixing in the alicyclic olefin polymer (A4) in the curable resin composition, the obtained electrical insulating layer (resin layer) became inferior in heat resistance (Comparative Example 2-3).

1.-12. (canceled)

13. A curable resin composition containing an epoxy compound (A1), active ester compound (A2), filler (A3), and alicyclic olefin polymer (A4) containing groups which have reactivity with respect to epoxy groups,
wherein a ratio of content of said alicyclic olefin polymer (A4) to 100 parts by weight of said epoxy compound (A1) is 2 to 50 parts by weight.

14. The curable resin composition as set forth in claim 13, wherein a ratio of epoxy groups of said epoxy compound (A1) and active ester groups of said active ester compound (A2) and groups which have reactivity with respect to epoxy groups of said alicyclic olefin polymer (A4) is an equivalent ratio of “epoxy groups/(active ester groups+groups which have reactivity with respect to epoxy groups)” of 0.8 to 1.2.

15. A film which is comprised of the resin composition as set forth in claim 13.

16. A film which has an adhesive layer which is comprised of the curable resin composition as set forth in claim 13 and a plateable layer which is comprised of a plateable layer-use resin composition.

17. The film as set forth in claim 16, wherein the plateable layer-use resin composition contains an alicyclic olefin polymer (B1) containing polar groups and a curing agent (B2).

18. The film as set forth in claim 16, wherein said adhesive layer has a thickness of 10 to 100 μm and said plateable layer has a thickness of 1 to 10 μm.

19. A prepreg obtained by impregnating the curable resin composition as set forth in claim 13 in a fiber base material.

20. A prepreg which is comprised of the film as set forth in claim 16 and a fiber base material.

21. A laminate obtained by laminating the film as set forth in claim 15 on a base material.

22. A laminate obtained by laminating the film as set forth in claim 16.

23. A cured article obtained by curing the curable resin composition as set forth in claim 13.

24. A cured article obtained by curing the film as set forth in claim 15.

25. A cured article obtained by curing the film as set forth in claim 16.

26. A cured article obtained by curing the prepreg as set forth in claim 19.

27. A cured article obtained by curing the prepreg as set forth in claim 20.

28. A composite article obtained by forming a conductor layer on the surface of the cured article as set forth in claim 25 by electroless plating.

29. A composite article obtained by forming a conductor layer on the surface of the cured article as set forth in claim 27 by electroless plating.

30. A substrate for electronic material-use which is comprised of the composite article as set forth in claim 28 as a component material.

31. A substrate for electronic material-use which is comprised of the composite article as set forth in claim 29 as a component material.
